(19) United States
(12) Patent Application Publication
(10) Pub. No.: US 2023/0124349 A1
(43) Pub. Date: Apr. 20, 2023

(54) ORGANIC MOLECULES FOR OPTOELECTRONIC DEVICES

(71) Applicant: Samsung Display Co., Ltd., Yongin-si, Gyeonggi-do (KR)

(72) Inventors: SEIFERMANN Stefan, Bühl (DE); KASPAREK Christian, Heidelberg (DE); SCHMALZL Markus, Bad Schönborn (DE)

(21) Appl. No.: 17/911,997

(22) PCT Filed: Dec. 16, 2020
(86) PCT No.: PCT/EP2020/086435

§ 371 Date: Sep. 15, 2022

(30) Foreign Application Priority Data
Dec. 20, 2019 (EP) 19218803.5

(51) Int. Cl. C07F 5/02; H10K 85/60; H10K 71/16

(52) U.S. Cl. CPC C07F 5/027; H10K 85/658; H10K 71/164; H10K 2102/301

(57) ABSTRACT

The invention relates to an organic molecule, in particular for the application in optoelectronic devices. According to the invention, the organic molecule has a structure of formula (I) wherein R^{I}, R^{II}, R^{III}, R^{IV}, R^{V}, R^{VI}, R^{VII}, R^{VIII}, R^{IX}, R^{X} and R^{XI} are independently selected from the group consisting of: hydrogen, deuterium, halogen, C₁-C₁₂-alkyl, wherein optionally one or more hydrogen atoms are independently substituted by R⁵; C₆-C₁₈-aryl, wherein optionally one or more hydrogen atoms are independently substituted R⁵; R⁵ is at each occurrence independently selected from the group consisting of: hydrogen, deuterium C₁-C₁₂-alkyl, C₆-C₁₈-aryl, wherein optionally one or more hydrogen atoms are independently substituted by C₁-C₅-alkyl substituents; at least one of R^{I}, R^{II}, R^{III}, R^{IV}, R^{V} and at least one of R^{VI}, R^{VII}, R^{VIII}, R^{IX} or R^{X} is selected from the group of: C₁-C₁₂-alkyl, wherein optionally one or more hydrogen atoms are independently substituted by R⁵; C₆-C₁₈-aryl, wherein optionally one or more hydrogen atoms are independently substituted by R⁵; and each hydrogen may independently be substituted by deuterium or halogen.

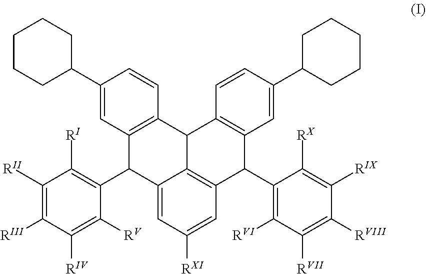

### CROSS-REFERENCE TO RELATED APPLICATIONS

This application is a U.S. National Phase Patent Application of International Patent Application Number PCT/EP2020/086435, filed on Dec. 16, 2020, which claims priority to European Patent Application Number 19218803.5, filed on Dec. 20, 2019, the entire content of all of which is incorporated herein by reference.

### BACKGROUND

One or more embodiments of the present disclosure relate to organic light-emitting molecules and their use in organic light-emitting diodes (OLEDs) and in other optoelectronic devices.

### DETAILED DESCRIPTION

One or more objects of the present disclosure is to provide molecules which are suitable for use in optoelectronic devices.

One or more embodiments of the present disclosure provide a new class of organic molecules.

According to the disclosure, the organic molecules are purely organic molecules, i.e. they do not contain any metal ions in contrast to metal complexes known for the use in optoelectronic devices. The organic molecules of the disclosure, however, include metalloids, for example B, Si, Sn, Se, and/or Ge.

According to the present disclosure, the organic molecules exhibit emission maxima in the blue, sky-blue or green spectral range. The organic molecules exhibit, for example, emission maxima between 420 nm and 520 nm, for example, between 440 nm and 495 nm, or between 450 nm and 470 nm. The photoluminescence quantum yields of the organic molecules according to the disclosure are, for example, 50% or more. The use of the molecules according to the disclosure in an optoelectronic device, for example an organic light-emitting diode (OLED), leads to higher efficiencies or higher color purity, expressed by the full width at half maximum (FWHM) of emission, of the device. Corresponding OLEDs have a higher stability than OLEDs with comparable emitter materials and comparable color.

The organic light-emitting molecules according to the disclosure comprise or consist of a structure of Formula I:

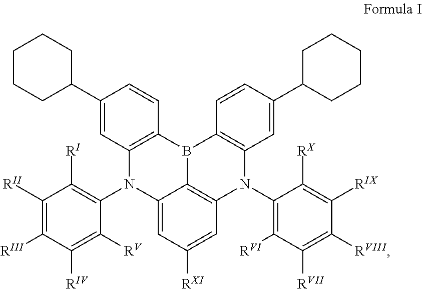

wherein

R^{I}, R^{II}, R^{III}, R^{IV}, R^{V}, R^{VI}, R^{VII}, R^{VIII}, R^{IX}, R^{X} and R^{XI} are each independently selected from the group consisting of:

hydrogen, halogen,

C₁-C₁₂-alkyl,

wherein optionally one or more hydrogen atoms are each independently substituted by R⁵; and

C₆-C₁₈-aryl,

wherein optionally one or more hydrogen atoms are each independently substituted R⁵.

R⁵ is at each occurrence independently selected from the group consisting of:

hydrogen,

C₁-C₁₂-alkyl, and

C₆-C₁₈-aryl,

wherein optionally one or more hydrogen atoms are each independently substituted by C₁-C₆-alkyl substituents.

At least one of R^{I}, R^{II}, R^{III}, R^{IV}, or R^{V} and at least one of R^{VI}, R^{VII}, R^{VIII}, R^{IX} or R^{X} are each selected from the group consisting of:

C₁-C₁₂-alkyl,

wherein optionally one or more hydrogen atoms are each independently substituted by R⁵; and

C₆-C₁₈-aryl,

wherein optionally one or more hydrogen atoms are each independently substituted by R⁵.

Optionally, each hydrogen is independently from each other substituted by deuterium or halogen.

In some embodiments of the organic molecule, each of R^{I}, R^{II}, R^{III}, R^{IV}, R^{V}, R^{VI}, R^{VII}, R^{VIII}, R^{IX}, R^{X} and R^{XI} is independently from each other selected from the group consisting of:

hydrogen, deuterium, halogen, Me, ⁱPr, ^{t}Bu,

cyclohexyl, which is optionally substituted with one or more substituents independently from each other selected from the group consisting of Me, ⁱPr, ^{t}Bu and phenyl (Ph); and

Ph, which is optionally substituted with one or more substituents independently from each other selected from the group consisting of Me, ⁱPr, ^{t}Bu, cyclohexyl and Ph.

In some embodiments, at least one of R^{I}, R^{II}, R^{III}, R^{IV}, or R^{V} and at least one of R^{VI}, R^{VII}, R^{VIII}, R^{IX} or R^{X} are independently from each other selected from the group consisting of Me, ⁱPr, ^{t}Bu, cyclohexyl and Ph.

In some embodiments, R^{IV} and R^{VII} are cyclohexyl.

In some embodiments, R^{II}, R^{IV}, R^{VII} and R^{IX} are ^{t}Bu.

In some embodiments, R^{XI} is selected from the group consisting of:

hydrogen, deuterium, halogen, Me, ⁱPr, ^{t}Bu,

cyclohexyl, which is optionally substituted with one or more substituents independently from each other selected from the group consisting of Me, ⁱPr, ^{t}Bu and phenyl (Ph); and

Ph, which is optionally substituted with one or more substituents independently from each other selected from the group consisting of Me, ⁱPr, ^{t}Bu, cyclohexyl and Ph.

In some embodiments, R^{XI} is selected from the group consisting of hydrogen, deuterium, Me. ⁱPr, ^{t}Bu, cyclohexyl and phenyl.

In some embodiments, R^{XI} is hydrogen.

In some embodiments, R^{XI} is Me.

In some embodiments, R^{XI} is phenyl.

In some embodiments, R^{I} is equal to (e.g., the same as) R^{X}, R^{II} is equal to R^{IX}, R^{III} is equal to R^{VIII}, R^{IV} is equal to R^{VII}, and R^{V} is equal to R^{VI}, such that the organic molecules of such embodiments comprise or include (e.g., consist of) a structure of Formula II:

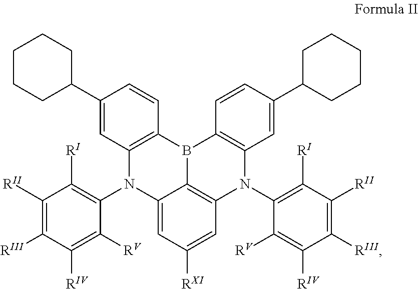

with the definitions as given above.

In one embodiment, the organic molecule comprises or includes (e.g., consists of) a structure of Formula Ia:

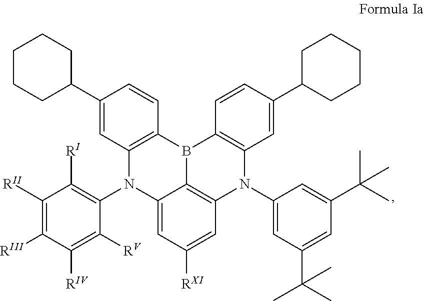

wherein R^{I}, R^{II}, R^{III}, R^{IV} and R^{V} are independently from each other selected from the group consisting of:

hydrogen, deuterium, halogen, Me, ⁱPr, ^{t}Bu,

cyclohexyl, which is optionally substituted with one or more substituents independently from each other selected from the group consisting of Me, ⁱPr, ^{t}Bu and Ph; and

Ph, which is optionally substituted with one or more substituents independently from each other selected from the group consisting of Me, ⁱPr, ^{t}Bu, cyclohexyl and Ph.

In one embodiment, the organic molecule comprises or includes (e.g., consists of) a structure of Formula Ia, wherein at least one of R^{I}, R^{II}, R^{III}, R^{IV}, or R^{V} is selected from the group consisting of Me, ⁱPr, ^{t}Bu, cyclohexyl and Ph.

In one or more embodiments, the organic molecule comprises or includes (e.g., consists of) a structure of Formula Ib:

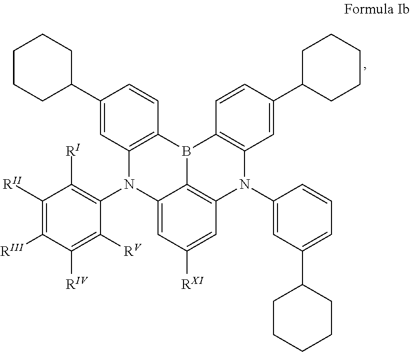

wherein R^{I}, R^{II}, R^{III}, R^{IV}, and R^{V} are independently from each other selected from the group consisting of:

hydrogen, deuterium, halogen, Me, ⁱPr, ^{t}Bu,

cyclohexyl, which is optionally substituted with one or more substituents independently from each other selected from the group consisting of Me, ⁱPr, ^{t}Bu and Ph; and

Ph, which is optionally substituted with one or more substituents independently from each other selected from the group consisting of Me, ⁱPr, ^{t}Bu, cyclohexyl and Ph.

In one embodiment, the organic molecule comprises or includes (e.g., consists of) a structure of Formula Ib, wherein at least two of R^{I}, R^{II}, R^{III}, R^{IV}, or R^{V} are independently from each other selected from the group consisting of Me, ⁱPr, ^{t}Bu, cyclohexyl and Ph.

In one or more embodiments, the organic molecule comprises or includes (e.g., consists of) a structure of Formula Ic:

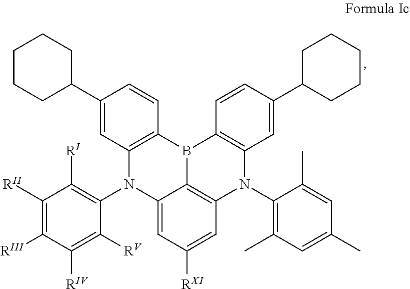

wherein R^{I}, R^{II}, R^{III}, R^{IV} and R^{V} are independently from each other selected from the group consisting of:

hydrogen, deuterium, halogen, Me, ⁱPr, ^{t}Bu,

cyclohexyl, which is optionally substituted with one or more substituents independently from each other selected from the group consisting of Me, ⁱPr, ^{t}Bu and Ph; and

Ph, which is optionally substituted with one or more substituents independently from each other selected from the group consisting of Me, ⁱPr, ^{t}Bu, cyclohexyl and Ph.

In one embodiment, the organic molecule comprises or includes (e.g., consists of) a structure of Formula Ic, wherein at least two of R^{I}, R^{II}, R^{III}, R^{IV}, or R^{V} are independently from each other selected from the group consisting of Me, ⁱPr, ^{t}Bu, cyclohexyl and Ph.

In one or more embodiments, the organic molecule comprises or includes (e.g., consists of) a structure of Formula Id:

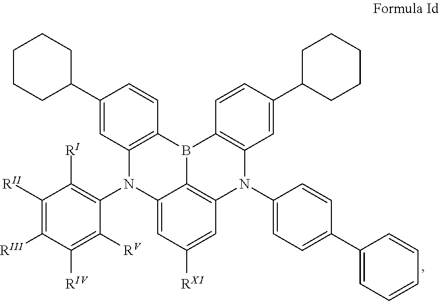

wherein R^{I}, R^{II}, R^{III}, R^{IV} and R^{V} are independently from each other selected from the group consisting of:

hydrogen, deuterium, halogen, Me, ⁱPr, ^{t}Bu,

cyclohexyl, which is optionally substituted with one or more substituents independently from each other selected from the group consisting of Me, ⁱPr, ^{t}Bu and Ph; and

Ph, which is optionally substituted with one or more substituents independently from each other selected from the group consisting of Me, ⁱPr, ^{t}Bu, cyclohexyl and Ph.

In one embodiment, the organic molecule comprises or includes (e.g., consists of) a structure of Formula Id, wherein at least two of R^{I}, R^{II}, R^{III}, R^{IV}, or R^{V} are independently from each other selected from the group consisting of Me, ⁱPr, ^{t}Bu, cyclohexyl and Ph.

In one or more embodiments, the organic molecule comprises or includes (e.g., consists of) a structure of Formula Ie:

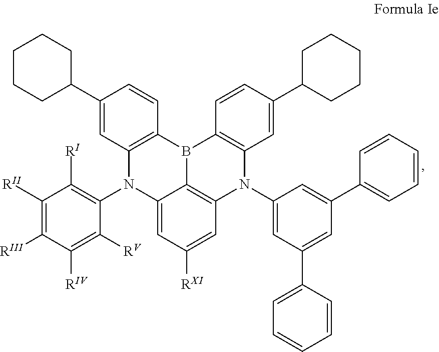

wherein R^{I}, R^{II}, R^{III}, R^{IV} and R^{V} are independently from each other selected from the group consisting of:

hydrogen, deuterium, halogen, Me, ⁱPr, ^{t}Bu,

cyclohexyl, which is optionally substituted with one or more substituents independently from each other selected from the group consisting of Me, ⁱPr, ^{t}Bu and Ph; and

Ph, which is optionally substituted with one or more substituents independently from each other selected from the group consisting of Me, ⁱPr, ^{t}Bu, cyclohexyl and Ph.

In one embodiment, the organic molecule comprises or includes (e.g., consists of) a structure of Formula Ie, wherein at least two of R^{I}, R^{II}, R^{III}, R^{IV}, or R^{V} are independently from each other selected from the group consisting of Me, ⁱPr, ^{t}Bu, cyclohexyl and Ph.

In one or more embodiments, the organic molecule comprises or includes (e.g., consists of) a structure of Formula If:

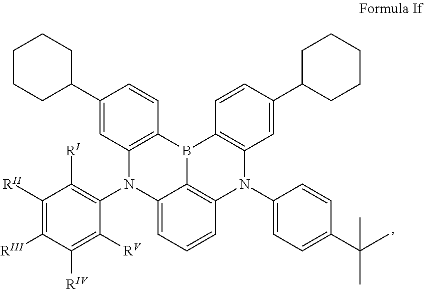

wherein R^{I}, R^{II}, R^{III}, R^{IV} and R^{V} are independently from each other selected from the group consisting of:

hydrogen, deuterium, halogen, Me, ⁱPr, ^{t}Bu,

cyclohexyl, which is optionally substituted with one or more substituents independently from each other selected from the group consisting of Me, ⁱPr, ^{t}Bu and Ph; and

Ph, which is optionally substituted with one or more substituents independently from each other selected from the group consisting of Me, ⁱPr, ^{t}Bu, cyclohexyl and Ph.

In one embodiment, the organic molecule comprises or includes (e.g., consists of) a structure of Formula If, wherein at least two of R^{I}, R^{II}, R^{III}, R^{IV}, or R^{V} are independently from each other selected from the group consisting of Me, ⁱPr, ^{t}Bu, cyclohexyl and Ph.

As used throughout the present application, the terms “aryl” and “aromatic” may be understood in the broadest sense as any mono-, bi- or polycyclic aromatic moiety. Accordingly, an aryl group contains 6 to 60 aromatic ring atoms, and a heteroaryl group contains 5 to 60 aromatic ring atoms, of which at least one is a heteroatom. Notwithstanding, throughout the application the number of aromatic ring atoms may be given as subscripted number in the definition of certain substituents. For example, the heteroaromatic ring includes one to three heteroatoms. Again, the terms “heteroaryl” and “heteroaromatic” may be understood in the broadest sense as any mono-, bi- or polycyclic hetero-aromatic moieties that include at least one heteroatom. The heteroatoms may at each occurrence be the same or different and be individually selected from the group consisting of N, O and S. Accordingly, the term “arylene” refers to a divalent substituent that bears two binding sites to other molecular structures and thereby serving as a linker structure. In case a group in the example embodiments is defined differently from the definitions given here, for example, the number of aromatic ring atoms and/or number of heteroatoms differs from the given definition, the definition in the example embodiments is to be applied. According to the disclosure, a condensed (annulated) aromatic or heteroaromatic polycycle is built of two or more single aromatic and/or heteroaromatic cycles, which formed the polycycle via a condensation reaction.

For example, as used throughout, the term “aryl group or heteroaryl group” comprises groups which can be bound via any position of the aromatic or heteroaromatic group, derived from benzene, naphthalene, anthracene, phenanthrene, pyrene, dihydropyrene, chrysene, perylene, fluoranthene, benzanthracene, benzophenanthrene, tetracene, pentacene, benzopyrene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthoimidazole, phenanthroimidazole, pyridoimidazole, pyrazinoimidazole, quinoxalinoimidazole, oxazole, benzoxazole, naphthooxazole, anthroxazole, phenanthroxazole, isoxazole, 1,2-thiazole, 1,3-thiazole, benzothiazole, pyridazine, benzopyridazine, pyrimidine, benzopyrimidine, 1,3,5-triazine, quinoxaline, pyrazine, phenazine, naphthyridine, carboline, benzocarboline, phenanthroline, 1,2,3-triazole, 1,2,4-triazole, benzotriazole, 1,2,3-oxadiazole, 1,2,4-oxadiazole, 1,2,5-oxadiazole, 1,2,3,4-tetrazine, purine, pteridine, indolizine and benzothiadiazole or combinations of the abovementioned groups.

As used throughout, the term “cyclic group” may be understood in the broadest sense as any mono-, bi- or polycyclic moiety.

As used throughout, the term “biphenyl” as a substituent may be understood in the broadest sense as ortho-biphenyl, meta-biphenyl, or para-biphenyl, wherein ortho, meta and para is defined in regard to the binding site to another chemical moiety.

As used throughout, the term “alkyl group” may be understood in the broadest sense as any linear, branched, or cyclic alkyl substituent. For example, the term alkyl comprises the substituents such as methyl (Me), ethyl (Et), n-propyl (ⁿPr), i-propyl (ⁱPr), cyclopropyl, n-butyl (ⁿBu), i-butyl (ⁱBu), s-butyl (^{s}Bu), t-butyl (^{t}Bu), cyclobutyl, 2-methylbutyl, n-pentyl, s-pentyl, t-pentyl, 2-pentyl, neo-pentyl, cyclopentyl, n-hexyl, s-hexyl, t-hexyl, 2-hexyl, 3-hexyl, neo-hexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2,2,2]octyl, 2-bicyclo[2,2,2]-octyl, 2-(2,6-dimethyl)octyl, 3-(3,7-dimethyl)octyl, adamantyl, 2,2,2-trifluorethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyln-n-hexadec-1-yl, 1,1-diethyl-n-octadec-1-yl, 1-(n-propyl)-cyclohex-1-yl, 1-(n-butyl)-cyclohex-1-yl, 1-(n-hexyl)-cyclohex-1-yl, 1-(n-octyl)-cyclohex-1-yl, and/or 1-(n-decyl)-cyclohex-1-yl.

As used throughout, the term “alkenyl” comprises linear, branched, and cyclic alkenyl substituents. The term “alkenyl group”, for example, comprises the substituents such as ethenyl, propenyl, butenyl, pentenyl, cyclopentenyl, hexenyl, cyclohexenyl, heptenyl, cycloheptenyl, octenyl, cyclooctenyl and/or cyclooctadienyl.

As used throughout, the term “alkynyl” comprises linear, branched, and cyclic alkynyl substituents. The term “alkynyl group”, for example, comprises ethynyl, propynyl, butynyl, pentynyl, hexynyl, heptynyl and/or octynyl.

As used throughout, the term “alkoxy” comprises linear, branched, and cyclic alkoxy substituents. The term “alkoxy group” exemplarily comprises methoxy, ethoxy, n-propoxy, i-propoxy, n-butoxy, i-butoxy, s-butoxy, t-butoxy and/or 2-methylbutoxy.

As used throughout, the term “thioalkoxy” comprises linear, branched, and cyclic thioalkoxy substituents, in which the O of the alkoxy groups is replaced by S.

As used throughout, the terms “halogen” and “halo” may be understood in the broadest sense as being, for example, fluorine, chlorine, bromine, and/or iodine.

Whenever hydrogen (H) is mentioned herein, it could also be replaced by deuterium at each occurrence.

It is to be understood that when a molecular fragment is described as being a substituent or otherwise attached to another moiety, its name may be written as if it were a fragment (e.g. naphthyl, dibenzofuryl) or as if it were the whole molecule (e.g. naphthalene, dibenzofuran). As used herein, these different ways of designating a substituent or attached fragment are considered to be equivalent.

In one or more embodiments, the organic molecules according to the disclosure have an excited state lifetime of not more than 150 μs, of not more than 100 μs, for example of not more than 50 μs, of not more than 10 μs, or not more than 7 μs in a film of poly(methyl methacrylate) (PMMA) with 5% by weight of organic molecule at room temperature.

In further embodiments of the disclosure, the organic molecules according to the disclosure have an emission peak in the visible or nearest ultraviolet range, e.g., in the wavelength range from 380 nm to 800 nm, with a full width at half maximum of less than 0.23 eV, for example, less than 0.20 eV, less than 0.19 eV, less than 0.18 eV, or less than 0.17 eV in a film of poly(methyl methacrylate) (PMMA) with 5% by weight of organic molecule at room temperature.

Orbital and excited state energies can be determined by means of one or more experimental methods. The energy of the highest occupied molecular orbital E^{HOMO} is determined by one or more suitable methods from cyclic voltammetry measurements with an accuracy of 0.1 eV. The energy of the lowest unoccupied molecular orbital E^{LUMO} is calculated as E^{HOMO}+E^{gap}, wherein E^{gap} is determined as follows: For host compounds, the onset of the emission spectrum of a film with 10% by weight of host in poly(methyl methacrylate) (PMMA) is used as E^{gap}, unless stated otherwise. For emitter molecules, E^{gap} is determined as the energy at which the excitation and emission spectra of a film with 10% by weight of emitter in PMMA cross. For the organic molecules according to the disclosure, E^{gap} is determined as the energy at which the excitation and emission spectra of a film with 5% by weight of emitter in PMMA cross (e.g., intersect).

The energy of the first excited triplet state T1 is determined from the onset of the emission spectrum at low temperature, for example, at 77 K. For host compounds, where the first excited singlet state and the lowest triplet state are energetically separated by >0.4 eV, the phosphorescence is usually visible in a steady-state spectrum in 2-Me-THF. The triplet energy can thus be determined as the onset of the phosphorescence spectrum. For TADF emitter molecules, the energy of the first excited triplet state T1 is determined from the onset of the delayed emission spectrum at 77 K, if not otherwise stated, measured in a film of PMMA with 10% by weight of emitter, and in case of the organic molecules according to the disclosure with 1% by weight of the organic molecules according to the disclosure. Both for host and emitter compounds, the energy of the first excited singlet state 51 is determined from the onset of the emission spectrum, if not otherwise stated, measured in a film of PMMA with 10% by weight of host or emitter compound, and in case of the organic molecules according to the disclosure with 1% by weight of the organic molecules according to the disclosure.

The onset of an emission spectrum is determined by computing the intersection of the tangent to the emission spectrum with the x-axis. The tangent to the emission spectrum is set at the high-energy side of the emission band and at the point at half maximum of the maximum intensity of the emission spectrum.

In one embodiment, the organic molecules according to the disclosure have an onset of the emission spectrum, which is energetically close to the emission maximum, e.g., the energy difference between the onset of the emission spectrum and the energy of the emission maximum is below 0.14 eV, for example, below 0.13 eV, or below 0.12 eV, while the full width at half maximum (FWHM) of the organic molecules is less than 0.23 eV, for example, less than 0.20 eV, less than 0.19 eV, less than 0.18 eV, or less than 0.17 eV in a film of poly(methyl methacrylate) (PMMA) with 5% by weight of organic molecule at room temperature, resulting in a CIEy coordinate below 0.20, for examply below 0.18, below 0.16, or below 0.14.

One or more further aspects of the present disclosure relate to the use of an organic molecule of the disclosure as a luminescent emitter or as an absorber, and/or as a host material and/or as an electron transport material, and/or as a hole injection material, and/or as a hole blocking material in an optoelectronic device.

One or more embodiments relate to the use of an organic molecule according to the disclosure as a luminescent emitter in an optoelectronic device.

The optoelectronic device may be understood in the broadest sense as any device based on organic materials that is suitable for emitting light in the visible or nearest ultraviolet (UV) range, e.g., in the wavelength range from 380 to 800 nm. For example, the optoelectronic device may be able to emit light in the visible range, e.g., from 400 nm to 800 nm.

In the context of such use, the optoelectronic device may be selected from the group consisting of:

organic light-emitting diodes (OLEDs),

light-emitting electrochemical cells,

OLED sensors, such as in gas and vapor sensors that are not hermetically shielded to the surroundings,

organic diodes,

organic solar cells,

organic transistors,

organic field-effect transistors,

organic lasers, and

down-conversion elements.

In one or more embodiments in the context of such use, the optoelectronic device is a device selected from the group consisting of an organic light emitting diode (OLED), a light emitting electrochemical cell (LEC), and a light-emitting transistor.

In the case of the use, the fraction (e.g., content) of the organic molecule according to the disclosure in the emission layer in an optoelectronic device, for example in an OLED, is 0.1% to 99% by weight, for example 1% to 80% by weight. In some embodiments, the proportion of the organic molecule in the emission layer is 100% by weight.

In one embodiment, the light-emitting layer comprises not only the organic molecules according to the disclosure, but also a host material whose triplet (T1) and singlet (S1) energy levels are energetically higher than the triplet (T1) and singlet (S1) energy levels of the organic molecule.

One or more further aspects of the disclosure relate to a composition comprising or including (e.g., consisting of):

(a) at least one organic molecule according to the disclosure, for example in the form of an emitter and/or a host, and

(b) one or more emitter and/or host materials, which differ from the organic molecule according to the disclosure and

(c) optional one or more dyes and/or one or more solvents.

In one embodiment, the light-emitting layer comprises (or essentially consists of) a composition comprising or including (e.g., consisting of):

(a) at least one organic molecule according to the disclosure, for example in the form of an emitter and/or a host, and

(b) one or more emitter and/or host materials, which differ from the organic molecule according to the disclosure and

(c) optional one or more dyes and/or one or more solvents.

In some embodiments, the light-emitting layer (EML) comprises (or essentially consists of) a composition comprising or including (e.g., consisting of):

(i) 0.1-10% by weight, for example 0.5-5% by weight, or 1-3% by weight, of one or more organic molecules according to the disclosure;

(ii) 5-99% by weight, for example 15-85% by weight, or 20-75% by weight, of at least one host compound H; and

(iii) 0.9-94.9% by weight, for example 14.5-80% by weight, or 24-77% by weight, of at least one further host compound D with a structure differing from the structure of the molecules according to the disclosure; and

(iv) optionally 0-94% by weight, for example 0-65% by weight, or 0-50% by weight, of a solvent; and

(v) optionally 0-30% by weight, for example 0-20% by weight, or 0-5% by weight, of at least one further emitter molecule F with a structure differing from the structure of the molecules according to the disclosure.

For example, energy can be transferred from the host compound H to the one or more organic molecules according to the disclosure, for example transferred from the first excited triplet state T1(H) of the host compound H to the first excited triplet state T1(E) of the one or more organic molecules E according to the disclosure and/or from the first excited singlet state S1(H) of the host compound H to the first excited singlet state S1(E) of the one or more organic molecules E according to the disclosure.

In one embodiment, the host compound H has a highest occupied molecular orbital HOMO(H) having an energy E^{HOMO}(H) in the range from −5 to −6.5 eV and the at least one further host compound D has a highest occupied molecular orbital HOMO(D) having an energy E^{HOMO}(D), wherein E^{HOMO}(H)>E^{HOMO}(D).

In a further embodiment, the host compound H has a lowest unoccupied molecular orbital LUMO(H) having an energy E^{LUMO}(H) and the at least one further host compound D has a lowest unoccupied molecular orbital LUMO(D) having an energy E^{LUMO}(D) wherein E^{LUMO}(H)>E^{LUMO}(D).

In one embodiment, the host compound H has a highest occupied molecular orbital HOMO(H) having an energy E^{HOMO}(H) and a lowest unoccupied molecular orbital LUMO(H) having an energy E^{LUMO}(H), and

the at least one further host compound D has a highest occupied molecular orbital HOMO(D) having an energy E^{HOMO}(D) and a lowest unoccupied molecular orbital LUMO(D) having an energy E^{LUMO}(D),

the organic molecule E according to the disclosure has a highest occupied molecular orbital HOMO(E) having an energy E^{HOMO}(E) and a lowest unoccupied molecular orbital LUMO(E) having an energy E^{LUMO}(E),

wherein

E^{HOMO}(H)>E^{HOMO}(D) and the difference between the energy level of the highest occupied molecular orbital HOMO(E) of the organic molecule E according to the disclosure (E^{HOMO}(E)) and the energy level of the highest occupied molecular orbital HOMO(H) of the host compound H (E^{HOMO}(H)) is between −0.5 eV and 0.5 eV, for example, between −0.3 eV and 0.3 eV, between −0.2 eV and 0.2 eV or between −0.1 eV and 0.1 eV; and

E^{LUMO}(H)>E^{LUMO}(D) and the difference between the energy level of the lowest unoccupied molecular orbital LUMO(E) of the organic molecule E according to the disclosure (E^{LUMO}(E)) and the lowest unoccupied molecular orbital LUMO(D) of the at least one further host compound D (E^{LUMO}(D)) is between −0.5 eV and 0.5 eV, for example, between −0.3 eV and 0.3 eV, between −0.2 eV and 0.2 eV or between −0.1 eV and 0.1 eV.

In one or more embodiments of the disclosure the host compound D and/or the host compound H is a thermally-activated delayed fluorescence (TADF)-material. TADF materials exhibit a ΔE_{ST} value, which corresponds to the energy difference between the first excited singlet state (S1) and the first excited triplet state (T1), of less than 2500 cm⁻¹. For example, the TADF material exhibits a ΔE_{ST} value of less than 3000 cm⁻¹, for example, less than 1500 cm⁻¹, less than 1000 cm⁻¹ or less than 500 cm⁻¹.

In one embodiment, the host compound D is a TADF material and the host compound H exhibits a ΔE_{ST} value of more than 2500 cm⁻¹. For example, the host compound D is a TADF material and the host compound H is selected from group consisting of CBP, mCP, mCBP, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole, and 9-[3,5-bis(2-dibenzothiophenyl)phenyl]-9H-carbazole.

In one embodiment, the host compound H is a TADF material and the host compound D exhibits a ΔE_{ST} value of more than 2500 cm⁻¹. For example, the host compound H is a TADF material and the host compound D is selected from group consisting of T2T (2,4,6-tris(biphenyl-3-yl)-1,3,5-triazine), T3T (2,4,6-tris(triphenyl-3-yl)-1,3,5-triazine) and/or TST (2,4,6-tris(9,9′-spirobifluorene-2-yl)-1,3,5-triazine).

In a further aspect, the disclosure relates to an optoelectronic device comprising an organic molecule or a composition of the type (or kind) described here, for example, in the form of a device selected from the group consisting of organic light-emitting diode (OLED), light-emitting electrochemical cell, OLED sensor such as gas and vapour sensors not hermetically externally shielded, organic diode, organic solar cell, organic transistor, organic field-effect transistor, organic laser and down-conversion element.

In some embodiments, the optoelectronic device is a device selected from the group consisting of an organic light emitting diode (OLED), a light emitting electrochemical cell (LEC), and a light-emitting transistor.

In one embodiment of the optoelectronic device of the disclosure, the organic molecule E according to the disclosure is used as emission material in a light-emitting layer (EML).

In one embodiment of the optoelectronic device of the disclosure, the light-emitting layer (EML) includes (e.g., consists of) the composition according to the disclosure described here.

When the optoelectronic device is an OLED, it may, for example, have the following layer structure:

1. substrate

2. anode layer A

3. hole injection layer, HIL

4. hole transport layer, HTL

5. electron blocking layer, EBL

6. emitting layer, EML

7. hole blocking layer, HBL

8. electron transport layer, ETL

9. electron injection layer, EIL

10. cathode layer,

wherein the OLED comprises each layer selected from the group of HIL, HTL, EBL, HBL, ETL, and EIL only optionally, different layers may be merged and the OLED may comprise more than one layer of each layer type (or kind) defined above.

Furthermore, the optoelectronic device may, in one embodiment, comprise one or more protective layers protecting the device from damaging exposure to harmful species in the environment including, for example, moisture, vapor and/or gases.

In one embodiment of the disclosure, the optoelectronic device is an OLED, with the following inverted layer structure:

1. substrate

2. cathode layer

3. electron injection layer, EIL

4. electron transport layer, ETL

5. hole blocking layer, HBL

6. emitting layer, B

7. electron blocking layer, EBL

8. hole transport layer, HTL

9. hole injection layer, HIL

10. anode layer A

wherein the OLED comprises each layer selected from the group of HIL, HTL, EBL, HBL, ETL, and EIL only optionally, different layers may be merged and the OLED may comprise more than one layer of each layer type (or kind) defined above.

In one or more embodiments of the disclosure, the optoelectronic device is an OLED, which may have a stacked architecture. In this architecture, contrary to the typical arrangement in which the OLEDs are placed side by side, the individual units are stacked on top of each other. Blended light may be generated with OLEDs exhibiting a stacked architecture, for example white light may be generated by stacking blue, green and red OLEDs. Furthermore, the OLED exhibiting a stacked architecture may comprise a charge generation layer (CGL), which may be located between two OLED subunits and may include (e.g., consists of) a n-doped and p-doped layer with the n-doped layer of one CGL being located closer to the anode layer.

In one or more embodiments of the disclosure, the optoelectronic device is an OLED, which comprises two or more emission layers between anode and cathode. For example, this so-called tandem OLED comprises three emission layers, wherein one emission layer emits red light, one emission layer emits green light and one emission layer emits blue light, and optionally may comprise further layers such as charge generation layers, blocking and/or transporting layers between the individual emission layers. In a further embodiment, the emission layers are adjacently stacked. In a further embodiment, the tandem OLED comprises a charge generation layer between each two emission layers. In addition, adjacent emission layers or emission layers separated by a charge generation layer may be merged.

The substrate may be formed by any suitable material or composition of materials. For example, glass slides may be used as substrates. In some embodiments, thin metal layers (e.g., copper, gold, silver or aluminum films) or plastic films or slides may be used. This may allow for a higher degree of flexibility. The anode layer A is mostly composed of materials allowing to obtain an (essentially) transparent film. As at least one of both electrodes should be (essentially) transparent in order to allow light emission from the OLED, either the anode layer A or the cathode layer C is transparent. For example, the anode layer A comprises a large content (e.g., amount) or even consists of transparent conductive oxides (TCOs). Such anode layer A may, for example, comprise indium tin oxide, aluminum zinc oxide, fluorine doped tin oxide, indium zinc oxide, PbO, SnO, zirconium oxide, molybdenum oxide, vanadium oxide, tungsten oxide, graphite, doped Si, doped Ge, doped GaAs, doped polyaniline, doped polypyrrole and/or doped polythiophene.

The anode layer A (essentially) may include (e.g., consist of) indium tin oxide (ITO) (e.g., (InO₃)_{0.9}(SnO₂)_{0.1}). The roughness of the anode layer A caused by the transparent conductive oxides (TCOs) may be compensated by using a hole injection layer (HIL). Further, the HIL may facilitate the injection of quasi charge carriers (i.e., holes) in that the transport of the quasi charge carriers from the TCO to the hole transport layer (HTL) is facilitated. The hole injection layer (HIL) may comprise poly-3,4-ethylendioxy thiophene (PEDOT), polystyrene sulfonate (PSS), MoO₂, V₂O₅, CuPC or CuI, for example a mixture of PEDOT and PSS. The hole injection layer (HIL) may also prevent or protect the diffusion of metals from the anode layer A into the hole transport layer (HTL). The HIL may, for example, comprise PEDOT:PSS (poly-3,4-ethylendioxy thiophene: polystyrene sulfonate), PEDOT (poly-3,4-ethylendioxy thiophene), mMTDATA (4,4′,4″-tris[phenyl(m-tolyl)amino]triphenylamine), Spiro-TAD (2,2′,7,7′-tetrakis(n,n-diphenylamino)-9,9′-spirobifluorene), DNTPD (N1,N1′-(biphenyl-4,4′-diyl)bis(N1-phenyl-N4,N4-di-m-tolylbenzene-1,4-diamine)), NPB (N,N′-nis-(1-naphthalenyl)-N,N′-bis-phenyl-(1,1′-biphenyl)-4,4′-diamine), NPNPB (N,N′-diphenyl-N,N′-di-[4-(N,N-diphenyl-amino)phenyl]benzidine), MeO-TPD (N,N,N′,N′-tetrakis(4-methoxyphenyl)benzidine), HAT-CN (1,4,5,8,9,12-hexaazatriphenylen-hexacarbonitrile) and/or Spiro-NPD (N,N′-diphenyl-N,N′-bis-(1-naphthyl)-9,9′-spirobifluorene-2,7-diamine).

Adjacent to the anode layer A or hole injection layer (HIL), a hole transport layer (HTL) may be located. Herein, any suitable hole transport compound may be used. For example, electron-rich heteroaromatic compounds such as triarylamines and/or carbazoles may be used as hole transport compound. The HTL may decrease the energy barrier between the anode layer A and the light-emitting layer (EML). The hole transport layer (HTL) may also be an electron blocking layer (EBL). For example, hole transport compounds bear comparably high energy levels of their triplet states T1. For example, the hole transport layer (HTL) may comprise a star-shaped heterocycle such as tris(4-carbazoyl-9-ylphenyl)amine (TCTA), poly-TPD (poly(4-butylphenyl-diphenyl-amine)), [alpha]-NPD (poly(4-butylphenyl-diphenyl-amine)), TAPC (4,4′-cyclohexyliden-bis[N, N-bis(4-methylphenyl)benzenamine]), 2-TNATA (4,4′,4″-tris[2-naphthyl(phenyl)amino]triphenylamine), Spiro-TAD, DNTPD, NPB, NPNPB, MeO-TPD, HAT-CN and/or TrisPcz (9,9′-diphenyl-6-(9-phenyl-9H-carbazol-3-yl)-9H,9′H-3,3′-bicarbazole). In addition, the HTL may comprise a p-doped layer, which may be composed of an inorganic or organic dopant in an organic hole-transporting matrix. Transition metal oxides such as vanadium oxide, molybdenum oxide or tungsten oxide may, for example, be used as inorganic dopant. Tetrafluorotetracyanoquinodimethane (F4-TCNQ), copper-pentafluorobenzoate (Cu(I)pFBz) or transition metal complexes may, for example, be used as organic dopant.

The EBL may, for example, comprise mCP (1,3-bis(carbazol-9-yl)benzene), TCTA, 2-TNATA, mCBP (3,3-di(9H-carbazol-9-yl)biphenyl), tris-Pcz, CzSi (9-(4-tert-Butylphenyl)-3,6-bis(triphenylsilyl)-9H-carbazole), and/or DCB (N,N′-dicarbazolyl-1,4-dimethylbenzene).

Adjacent to the hole transport layer (HTL), the light-emitting layer (EML) may be located. The light-emitting layer (EML) comprises at least one light emitting molecule. For example, the EML comprises at least one light emitting molecule E according to the disclosure. In one embodiment, the light-emitting layer comprises only the organic molecules according to the disclosure. Typically, the EML additionally comprises one or more host materials H. For example, the host material H is selected from CBP (4,4′-Bis-(N-carbazolyl)-biphenyl), mCP, mCBP Sif87 (dibenzo[b,d]thiophen-2-yltriphenylsilane), CzSi, Sif88 ((dibenzo[b,d]thiophen-2-yl)diphenylsilane), DPEPO (bis[2-(diphenylphosphino)phenyl] ether oxide), 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole, 9-[3,5-bis(2-dibenzothiophenyl)phenyl]-9H-carbazole, T2T (2,4,6-tris(biphenyl-3-yl)-1,3,5-triazine), T3T (2,4,6-tris(triphenyl-3-yl)-1,3,5-triazine) and/or TST (2,4,6-tris(9,9′-spirobifluorene-2-yl)-1,3,5-triazine). The host material H typically should be selected to exhibit first triplet (T1) and first singlet (S1) energy levels, which are energetically higher than the first triplet (T1) and first singlet (S1) energy levels of the organic molecule.

In one embodiment of the disclosure, the EML comprises a mixed-host system with at least one hole-dominant host and one electron-dominant host. In some embodiments, the EML comprises exactly one light emitting organic molecule according to the disclosure and a mixed-host system comprising T2T as electron-dominant host and a host selected from CBP, mCP, mCBP, 9-[3-(dibenzofuran-2-yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole as hole-dominant host.

In a further embodiment, the EML comprises 50-80% by weight, for example 60-75% by weight of a host selected from CBP, mCP, mCBP, 9-[3-(dibenzofuran yl)phenyl]-9H-carbazole, 9-[3-(dibenzothiophen-2-yl)phenyl]-9H-carbazole, 9-[3,5-bis(2-dibenzofuranyl)phenyl]-9H-carbazole and 9-[3,5-bis(2-dibenzothiophenyl)phenyl]-9H-carbazole; 10-45% by weight, for example, 15-30% by weight of T2T; and 5-40% by weight, for example 10-30% by weight of light emitting molecule according to the disclosure.

Adjacent to the light-emitting layer (EML), an electron transport layer (ETL) may be located. Herein, any electron transporter may be used. Exemplarily, electron-poor compounds such as, e.g., benzimidazoles, pyridines, triazoles, oxadiazoles (e.g., 1,3,4-oxadiazole), phosphinoxides and sulfone, may be used. An electron transporter may also be a star-shaped heterocycle such as 1,3,5-tri(1-phenyl-1H-benzo[d]imidazol-2-yl)phenyl (TPBi). The ETL may comprise NBphen (2,9-bis(naphthalen-2-yl)-4,7-diphenyl-1,10-phenanthroline), Alq₃ (Aluminum-tris(8-hydroxyquinoline)), TSPO1 (diphenyl-4-triphenylsilylphenyl-phosphinoxide), BPyTP2 (2,7-di(2,2′-bipyridin-5-yl)triphenyle), Sif87 (dibenzo[b,d]thiophen-2-yltriphenylsilane), Sif88 ((dibenzo[b,d]thiophen-2-yl)diphenylsilane), BmPyPhB (1,3-bis[3,5-di(pyridin-3-yl)phenyl]benzene) and/or BTB (4,4′-bis-[2-(4,6-diphenyl-1,3,5-triazinyl)]-1,1′-biphenyl). Optionally, the ETL may be doped with materials such as Liq. The electron transport layer (ETL) may also block or reduce holes or a hole blocking layer (HBL) may be introduced.

The HBL may, for example, comprise BCP (2,9-dimethyl-4,7-diphenyl-1,10-phenanthroline=Bathocuproine), BAlq (bis(8-hydroxy-2-methylquinoline)-(4-phenylphenoxy)aluminum), NBphen (2,9-bis(naphthalen-2-yl)-4,7-diphenyl-1,10-phenanthroline), Alq₃ (Aluminum-tris(8-hydroxyquinoline)), TSPO1 (diphenyl triphenylsilylphenyl-phosphinoxide), T2T (2,4,6-tris(biphenyl-3-yl)-1,3,5-triazine), T3T (2,4,6-tris(triphenyl-3-yl)-1,3,5-triazine), TST (2,4,6-tris(9,9′-spirobifluorene-2-yl)-1,3,5-triazine), and/or TCB/TCP (1,3,5-tris(N-carbazolyl)benzol/1,3,5-tris(carbazol)-9-yl) benzene).

Adjacent to the electron transport layer (ETL), a cathode layer C may be located. The cathode layer C may, for example, comprise or may include (e.g., consist of) a metal (e.g., Al, Au, Ag, Pt, Cu, Zn, Ni, Fe, Pb, LiF, Ca, Ba, Mg, In, W, or Pd) or a metal alloy. For practical reasons, the cathode layer may also include (e.g., consist of) (essentially) nontransparent metals such as Mg, Ca or Al. Alternatively or additionally, the cathode layer C may also comprise graphite and/or carbon nanotubes (CNTs). In some embodiments, the cathode layer C may also include (e.g., consist of) nanoscalic (e.g., nanoscale) silver wires.

An OLED may further, optionally, comprise a protection layer between the electron transport layer (ETL) and the cathode layer C (which may be designated as electron injection layer (EIL)). This layer may comprise lithium fluoride, cesium fluoride, silver, Liq (8-hydroxyquinolinolatolithium), Li₂O, BaF₂, MgO and/or NaF.

Optionally, the electron transport layer (ETL) and/or a hole blocking layer (HBL) may also comprise one or more host compounds H.

In order to modify the emission spectrum and/or the absorption spectrum of the light-emitting layer (EML) further, the light-emitting layer (EML) may further comprise one or more further emitter molecules F. Such an emitter molecule F may be any suitable emitter molecule known in the art. For example, such an emitter molecule F is a molecule with a structure differing from the structure of the molecules according to the disclosure E. The emitter molecule F may optionally be a TADF emitter. In some embodiments, the emitter molecule F may optionally be a fluorescent and/or phosphorescent emitter molecule which is able to shift the emission spectrum and/or the absorption spectrum of the light-emitting layer (EML). Exemplarily, the triplet and/or singlet excitons may be transferred from the organic emitter molecule according to the disclosure to the emitter molecule F before relaxing to the ground state S0 by emitting light typically red-shifted in comparison to the light emitted by an organic molecule. Optionally, the emitter molecule F may also provoke two-photon effects (i.e., the absorption of two photons of half the energy of the absorption maximum).

In one or more embodiments, an optoelectronic device (e.g., an OLED) may, for example, be an essentially white optoelectronic device. For example, such white optoelectronic device may comprise at least one (deep) blue emitter molecule and one or more emitter molecules emitting green and/or red light. Then, there may also optionally be energy transmittance between two or more molecules as described above.

As used herein, if not defined more specifically in the particular context, the designation of the colors of emitted and/or absorbed light is as follows:

violet: wavelength range of >380-420 nm;

deep blue: wavelength range of >420-480 nm;

sky blue: wavelength range of >480-500 nm;

green: wavelength range of >500-560 nm;

yellow: wavelength range of >560-580 nm;

orange: wavelength range of >580-620 nm;

red: wavelength range of >620-800 nm.

With respect to emitter molecules, such colors refer to the emission maximum. Therefore, for example, a deep blue emitter has an emission maximum in the range of from >420 to 480 nm, a sky blue emitter has an emission maximum in the range of from >480 to 500 nm, a green emitter has an emission maximum in a range of from >500 to 560 nm, a red emitter has an emission maximum in a range of from >620 to 800 nm.

A deep blue emitter may have an emission maximum of below 480 nm, for example below 470 nm, below 465 nm, or below 460 nm. For example, the emission maximum may be above 420 nm, for example, above 430 nm, above 440 nm or above 450 nm.

One or more further aspects of the present disclosure relate to an OLED, which exhibits an external quantum efficiency at 1000 cd/m² of more than 8%, for example, of more than 10%, of more than 13%, of more than 15% or more than 20% and/or exhibits an emission maximum between 420 nm and 500 nm, for example between 430 nm and 490 nm, between 440 nm and 480 nm, between 450 nm and 470 nm and/or exhibits a LT80 value at 500 cd/m² of more than 100 h, for example more than 200 h, more than 400 h, more than 750 h, or more than 1000 h. Accordingly, a further aspect of the present disclosure relates to an OLED, whose emission exhibits a CIEy color coordinate of less than 0.45, for example less than 0.30, less than 0.20 or less than 0.15 or even less than 0.10.

One or more further aspects of the present disclosure relate to an OLED, which emits light at a distinct color point. According to the present disclosure, the OLED emits light with a narrow emission band (small full width at half maximum (FWHM)). In one aspect, the OLED according to the disclosure emits light with a FWHM of the main emission peak of less than 0.30 eV, for example less than 0.25 eV, less than 0.20 eV, less than 0.19 eV, or even less than 0.17 eV.

A further aspect of the present disclosure relates to an OLED, which emits light with CIEx and CIEy color coordinates close to the CIEx (=0.131) and CIEy (=0.046) color coordinates of the primary color blue (CIEx=0.131 and CIEy=0.046) as defined by ITU-R Recommendation BT.2020 (Rec. 2020) and thus is suited for the use in Ultra High Definition (UHD) displays, e.g. UHD-TVs. Accordingly, a further aspect of the present disclosure relates to an OLED, whose emission exhibits a CIEx color coordinate of between 0.02 and 0.30, for example between 0.03 and 0.25, between 0.05 and 0.20 or between 0.08 and 0.18 or even between 0.10 and 0.15 and/or a CIEy color coordinate of between 0.00 and 0.45, for example between 0.01 and 0.30, between 0.02 and 0.20 or between 0.03 and 0.15 or even between 0.04 and 0.10.

In a further aspect, the disclosure relates to a method for producing an optoelectronic component. In this case an organic molecule of the disclosure is used.

The optoelectronic device, for example the OLED according to the present disclosure can be fabricated by any suitable means such as vapor deposition and/or liquid processing. Accordingly, at least one layer is
prepared by means of a sublimation process,
prepared by means of an organic vapor phase deposition process,
prepared by means of a carrier gas sublimation process, and/or
solution processed or printed.

The methods used to fabricate the optoelectronic device, for example the OLED according to the present disclosure are known in the art. The different layers are individually and successively deposited on a suitable substrate by means of subsequent deposition processes. The individual layers may be deposited using the same or differing deposition methods.

Vapor deposition processes, for example, comprise thermal (co)evaporation, chemical vapor deposition and physical vapor deposition. For active matrix OLED display, an AMOLED backplane is used as substrate. The individual layer may be processed from solutions or dispersions employing adequate solvents. Solution deposition process, for example, comprise spin coating, dip coating and jet printing. Liquid processing may optionally be carried out in an inert atmosphere (e.g., in a nitrogen atmosphere) and the solvent may be completely or partially removed by suitable means known in the state of the art.

### EXAMPLES

General Synthesis Scheme I

General Synthesis Scheme I provides a synthesis scheme for organic molecules according to the disclosure, wherein R^{I}=R^{X}, R^{II}=R^{IX}, R^{III}=R^{VIII}, R^{IV}=R^{VII}, and R^{V}=R^{VI}:

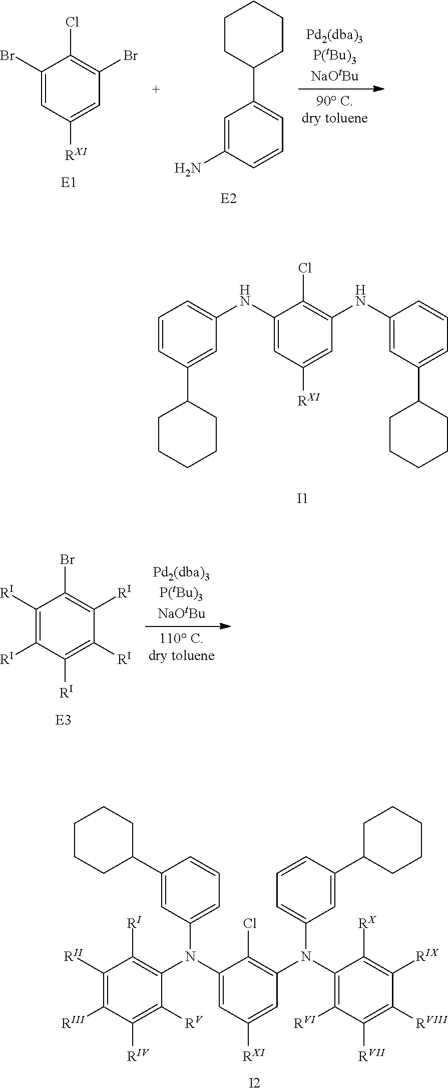

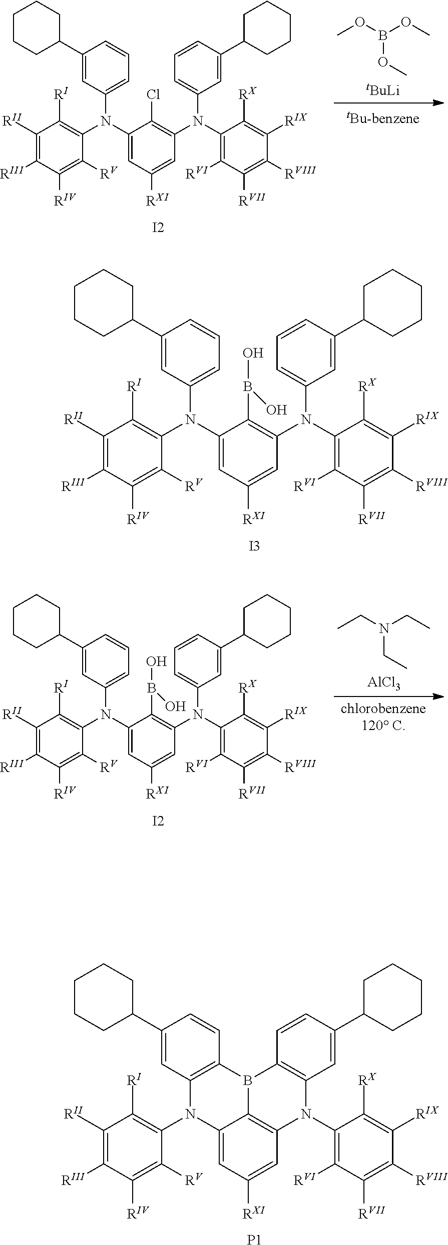

General procedure for synthesis AAV1:

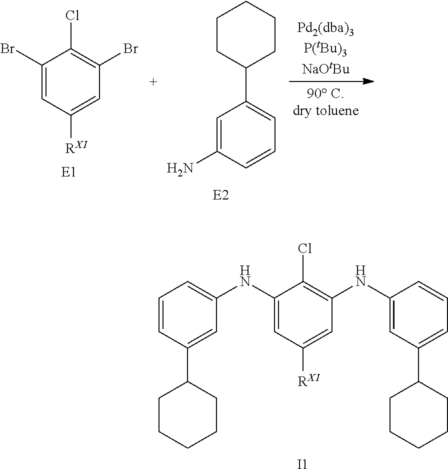

E1 (1.00 equivalent), 3-cyclohexylaniline (E2 2.20 equivalents, CAS: 5369-21-1), tris(dibenzylideneacetone)dipalladium Pd₂(dba)₃ (0.01 equivalents, CAS: 51364-51-3), tri-tert-butyl-phosphine P(^{t}Bu)₃ (0.04 equivalents, CAS: 13716-12-6) and sodium tert-butoxide NaO^{t}Bu (4.20 equivalents, CAS: 865-48-5) are stirred under nitrogen atmosphere in toluene at 90° C. After cooling down to room temperature (rt) the reaction mixture is extracted with toluene and brine and the phases are separated. The combined organic layers are dried over MgSO₄ and then the solvent is removed under reduced pressure. The crude product obtained is purified by recrystallization or column chromatography and 11 is obtained as solid.

General procedure for synthesis AAV2:

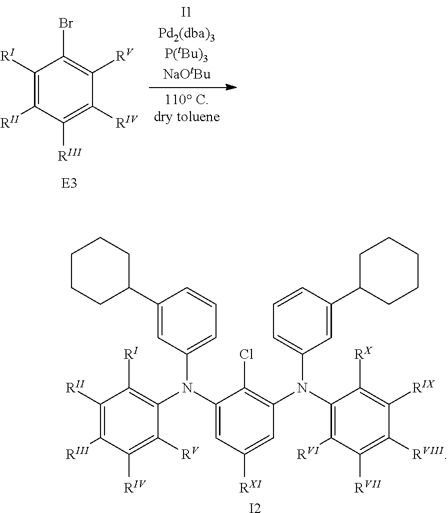

I1 (1.00 equivalents), E3 (2.10 equivalents), tris(dibenzylideneacetone)dipalladium Pd₂(dba)₃ (0.01 equivalents; CAS: 51364-51-3), tri-tert-butyl-phosphine P(^{t}Bu)₃ (0.04 equivalents, CAS: 13716-12-6) and sodium tert-butoxide NaO^{t}Bu (4.00 equivalents, CAS: 865-48-5) are stirred under nitrogen atmosphere in toluene at 110° C. After cooling down to room temperature (rt) the reaction mixture is extracted with toluene and brine and the phases are separated. The combined organic layers are dried over MgSO₄ and then the solvent is removed under reduced pressure. The crude product obtained is purified by recrystallization or column chromatography and 12 is obtained as solid.

General procedure for synthesis AAV3:

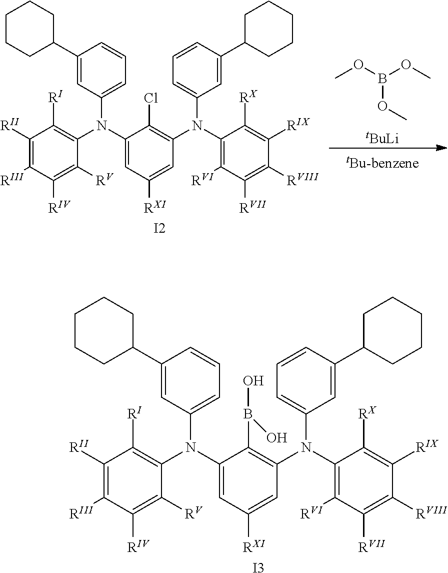

I2 (1 equivalent) is stirred under nitrogen atmosphere in ^{t}Bu-benzene at 40° C. Tert-butyllithium (^{t}BuLi, 5 equivalents, CAS 594-19-4) is added dropwise and the reaction is heated to 50° C. The lithiation is quenched by slowly adding trimethyl borate (6 equivalents, CAS 121-43-7) at room temperature. After heating the reaction mixture to 60° C. for 2 h, the reaction mixture is cooled down to room temperature. Water is added and the mixture is stirred for another 2 h. After extraction with ethyl acetate, the organic phase is dried over MgSO₄ and the solvent is removed under reduced pressure. The crude product obtained is purified by recrystallization or column chromatography and 13 is obtained as solid.

General procedure for synthesis AAV4:

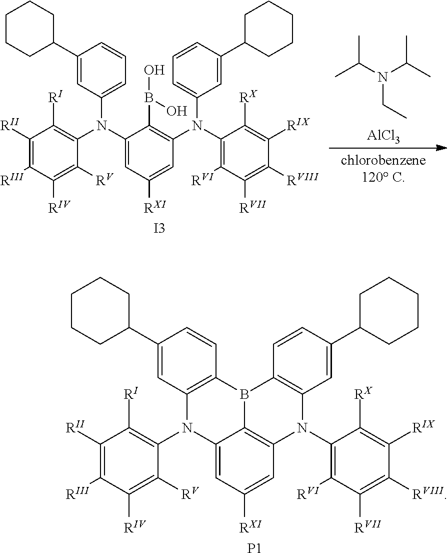

I3 (1 equivalent) is stirred and nitrogen atmosphere in chlorobenzene. N,N-diisopropylethylamine (10.0 equivalents, CAS 7087-68-5) and aluminum chloride (AlCl₃, 10.0 equivalents, CAS 7446-70-0) are added and the reaction mixture is heated to 120° C. After 60 min, N,N-diisopropylethylamine (5.00 equivalents, CAS 7087-68-5) and aluminum chloride (AlCl₃, 5.00 equivalents, CAS 7446-70-0) are added and the reaction mixture is stirred for 1.5 h. After cooling down to room temperature, the reaction mixture is extracted between DCM and water. The organic phase is dried over MgSO₄ and the solvent is partially removed under reduced pressure. Ethanol is added to the remaining organic phase and stored in a freezer for 1 h. The precipitated solid is then filtered and dried. The crude product P1 can be further purified by recrystallization or column chromatography.

General Synthesis Scheme II

General synthesis scheme II provides a synthesis scheme for organic molecules according to the disclosure, wherein R^{I}=R^{X}, R^{II}=R^{IX}, R^{III}=R^{VIII}, R^{IV}=R^{VII}, and R^{V}=R^{VI}:

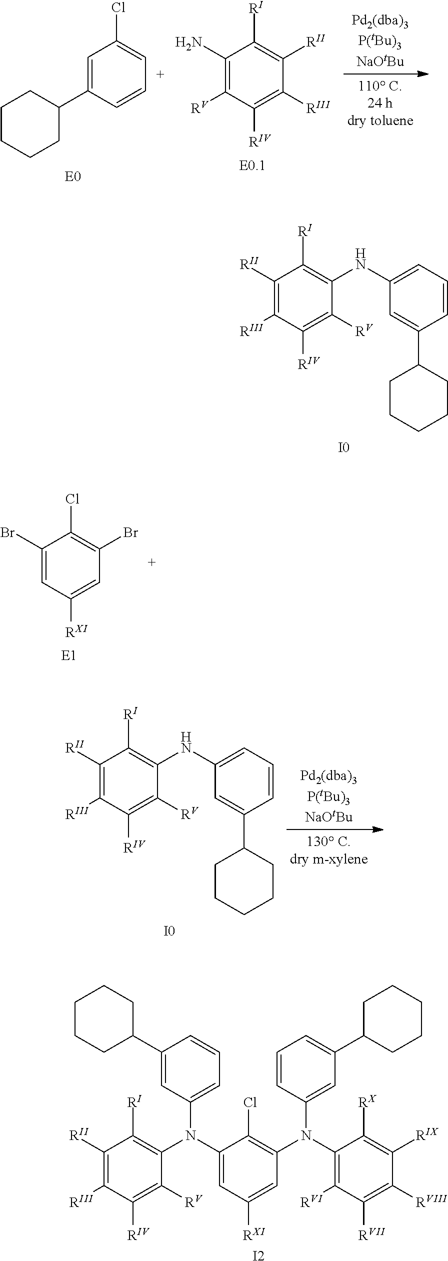

Alternative 1:

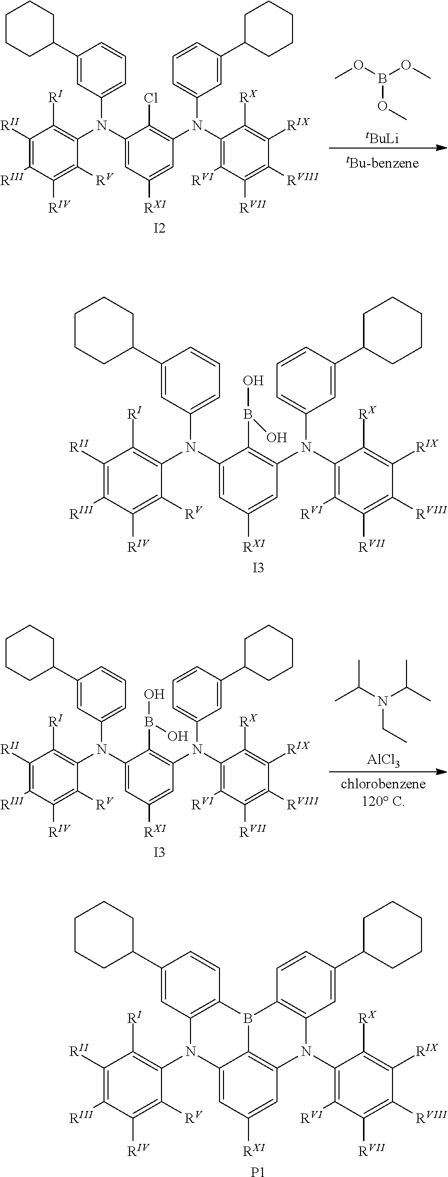

Alternative 2:

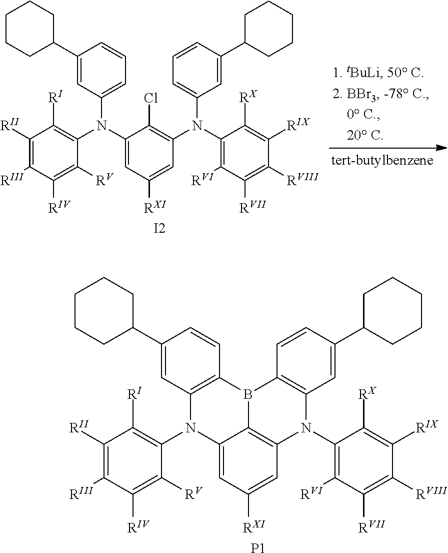

General procedure for synthesis AAV5:

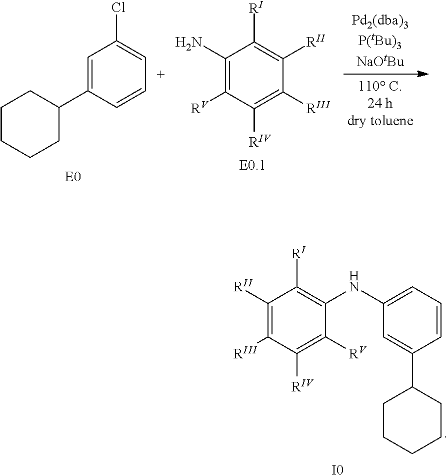

1-Chloro-3-cyclohexylbenzene (1 equivalents, CAS: 27163-66-2), E0.1 (2.00 equivalents), tris(dibenzylideneacetone)dipalladium Pd₂(dba)₃ (0.02 equivalents; CAS: 51364-51-3), tri-tert-butyl-phosphine (P(^{t}Bu)₃, CAS: 13716-12-6, 0.08 equivalents) and sodium tert-butoxide (NaO^{t}Bu; 3.00 equivalents) are stirred under nitrogen atmosphere in toluene at 110° C. for 24 h. After cooling down to room temperature (rt) the reaction mixture is extracted between toluene and brine and the phases are separated. The combined organic layers are dried over MgSO₄ and then the solvent is removed under reduced pressure. The crude product obtained is purified by recrystallization or column chromatography and I0 is obtained as solid.

General procedure for synthesis AAV6:

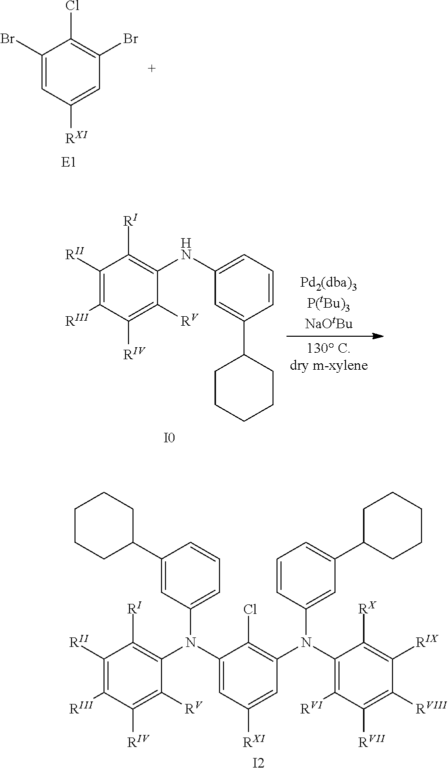

E1 (1.00 equivalent), 10 (2.20 equivalents), tris(dibenzylideneacetone)dipalladium Pd₂(dba)₃ (0.02 equivalents, CAS: 51364-51-3), tri-tert-butyl-phosphine P(^{t}Bu)₃ (0.08 equivalents, CAS: 13716-12-6) and sodium tert-butoxide NaO^{t}Bu (3.50 equivalents, CAS: 865-48-5) are stirred under nitrogen atmosphere in m-xylene at 130° C. for 2 h. After cooling down to room temperature (rt), the reaction mixture is extracted with toluene and brine and the phases are separated. The combined organic layers are dried over MgSO₄ and then the solvent is removed under reduced pressure. The crude product obtained is purified by recrystallization or column chromatography and I2 is obtained as solid.

The last synthesis steps of the General Synthesis Scheme II from 12 to P1 is carried out under similar conditions as described in AAV3 and AAV4 or AAV7.

General procedure for synthesis AAV7:

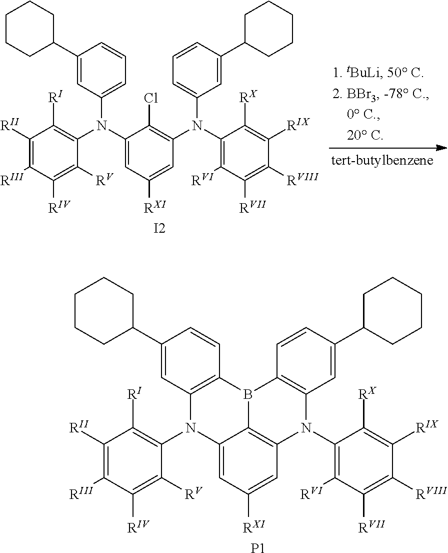

Under nitrogen atmosphere, aryl halide I2 is dissolved in dry tert-butylbenzene. At 50° C., tert-butyllithium (^{t}BuLi, 1.9 M in pentane, 2.20 equivalents, CAS 594-19-4) is added dropwise and stirring at 50° C. is continued for 1.5 h. Subsequently, the mixture is cooled down to −78° C. Boron tribromide (BBr₃, 1 M in hexane, 1.50 equivalents, CAS 10294-33-4) is added dropwise over 30 min. Subsequently, the temperature is raised to 0° C. After stirring at 0° C. for 1 h, the mixture is allowed to warm up to 20° C., and left stirring overnight. Subsequently, the reaction is quenched with NH₃ aq (5%), followed by phase separation and extraction of the aqueous layer with toluene. The combined organic layers are dried over MgSO₄, filtered and concentrated. The residue is purified by recrystallization.

Cyclic Voltammetry

Cyclic voltammograms are measured from solutions having concentration of 10⁻³ mol/L of the organic molecules in dichloromethane or a suitable solvent and a suitable supporting electrolyte (e.g. 0.1 mol/L of tetrabutylammonium hexafluorophosphate). The measurements are conducted at room temperature under nitrogen atmosphere with a three-electrode assembly (Working and counter electrodes: Pt wire, reference electrode: Pt wire) and calibrated using FeCp₂/FeCp₂⁺ as internal standard. The HOMO data was corrected using ferrocene as internal standard against a saturated calomel electrode (SCE).

Density Functional Theory Calculation

Molecular structures are optimized employing the BP86 functional and the resolution of identity approach (RI). Excitation energies are calculated using the (BP86) optimized structures employing Time-Dependent DFT (TD-DFT) methods. Orbital and excited state energies are calculated with the B3LYP functional. Def2-SVP basis sets (and a m4-grid for numerical integration are used). The Turbomole program package was used for all calculations.

Photophysical Measurements

Sample pretreatment: Spin-coating

Apparatus: Spin150, SPS euro.

The sample concentration is 10 mg/ml, dissolved in a suitable solvent.

Program: 1) 3 s at 400 U/min; 2) 20 s at 1000 U/min at 1000 Upm/s. 3) 10 s at 4000 U/m in at 1000 Upm/s. After coating, the films are dried at 70° C. for 1 min.

Photoluminescence spectroscopy and Time-Correlated Single-Photon Counting (TCSPC)

Steady-state emission spectroscopy is measured by a Horiba Scientific, Modell FluoroMax-4 equipped with a 150 W Xenon-Arc lamp, excitation- and emissions monochromators and a Hamamatsu R928 photomultiplier and a time-correlated single-photon counting option. Emissions and excitation spectra are corrected using standard correction fits.

Excited state lifetimes are determined employing the same system using the TCSPC method with FM-2013 equipment and a Horiba Yvon TCSPC hub.

Excitation sources:

NanoLED 370 (wavelength: 371 nm, puls duration: 1.1 ns)

NanoLED 290 (wavelength: 294 nm, puls duration: <1 ns)

SpectraLED 310 (wavelength: 314 nm)

SpectraLED 355 (wavelength: 355 nm).

Data analysis (exponential fit) is done using the software suite DataStation and DAS6 analysis software. The fit is specified using the chi-squared-test.

Photoluminescence quantum yield measurements

For photoluminescence quantum yield (PLQY) measurements an Absolute PL Quantum Yield Measurement C9920-03G system (Hamamatsu Photonics) is used. Quantum yields and CIE coordinates are determined using the software U6039-05 version 3.6.0.

Emission maxima are given in nm, quantum yields (I) in % and CIE coordinates as x,y values.

PLQY is determined using the following protocol:

Quality assurance: Anthracene in ethanol (known concentration) is used as reference.

Excitation wavelength: the absorption maximum of the organic molecule is determined and the molecule is excited using this wavelength.

Measurement:

Quantum yields are measured, for sample, of solutions or films under nitrogen atmosphere. The yield is calculated using the equation:

$${Φ}_{P L} = \frac{{n}_{pho ton} , emited}{{n}_{pho ton} , absorbed} = \frac{\int \frac{λ}{h c} [ {Int}_{emitted}^{sample} ( λ ) - {Int}_{absorbed}^{sample} ( λ ) ] dλ}{\int \frac{λ}{h c} [ {Int}_{emitted}^{reference} ( λ ) - {Int}_{absorbed}^{reference} ( λ ) ] dλ} ,$$

wherein nₚₕₒₜₒₙ denotes the photon count and Int. the intensity.

Production and Characterization of Optoelectronic Devices

Optoelectronic devices, for example OLED devices, comprising organic molecules according to the disclosure can be produced via vacuum-deposition methods. If a layer contains more than one compound, the weight-percentage of one or more compounds is given in %. The total weight-percentage values amount to 100%, thus if a value is not given, the fraction of this compound equals to the difference between the given values and 100%.

The not fully optimized OLEDs are characterized using standard methods and measuring electroluminescence spectra, the external quantum efficiency (in %) in dependency on the intensity, calculated using the light detected by the photodiode, and the current. The OLED device lifetime is extracted from the change of the luminance during operation at constant current density. The LT50 value corresponds to the time, where the measured luminance decreased to 50% of the initial luminance, analogously LT80 corresponds to the time point, at which the measured luminance decreased to 80% of the initial luminance, LT 95 to the time point, at which the measured luminance decreased to 95% of the initial luminance etc.

Accelerated lifetime measurements are performed (e.g. applying increased current densities). For example, LT80 values at 500 cd/m² are determined using the following equation:

$$LT 80 ( 500 \frac{cd}{{m}^{2}} ) = LT 80 ( {L}_{0} ) {( \frac{{L}_{0}}{500 \frac{cd}{{m}^{2}}} )}^{1.6} ,$$

wherein L₀ denotes the initial luminance at the applied current density.

The values correspond to the average of several pixels (typically two to eight), the standard deviation between these pixels is given.

HPLC-MS

HPLC-MS analysis is performed on an HPLC by Agilent (1100 series) with MS-detector (Thermo LTQ XL).

For example, a typical HPLC method is as follows: a reverse phase column 4.6 mm×150 mm, particle size 3.5 μm from Agilent (ZORBAX Eclipse Plus 95 Å C18, 4.6×150 mm, 3.5 μm HPLC column) is used in the HPLC. The HPLC-MS measurements are performed at room temperature (rt) following gradients

| Flow rate | Time | | | |
|---|---|---|---|---|
| [ml/min] | [min] | A[%] | B[%] | C[%] |
| 2.5 | 0 | 40 | 50 | 10 |
| 2.5 | 5 | 40 | 50 | 10 |
| 2.5 | 25 | 10 | 20 | 70 |
| 2.5 | 35 | 10 | 20 | 70 |
| 2.5 | 35.01 | 40 | 50 | 10 |
| 2.5 | 40.01 | 40 | 50 | 10 |
| 2.5 | 41.01 | 40 | 50 | 10 |

using the following solvent mixtures:

| | | |
|---|---|---|
| Solvent A: | H2O (90%) | MeCN (10%) |
| Solvent B: | H2O (10%) | MeCN (90%) |
| Solvent C: | THF (50%) | MeCN (50%) |

An injection volume of 5 μL from a solution with a concentration of 0.5 mg/mL of the analyte is taken for the measurements.

Ionization of the probe is performed using an atmospheric pressure chemical ionization (APCI) source either in positive (APCI+) or negative (APCI−) ionization mode.

### Example 1

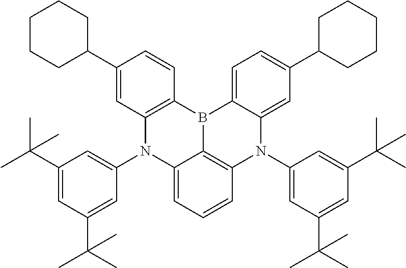 [SMILES: CC(C)(C)c1cc(N2c3cc(C4CCCCC4)ccc3B3c4ccc(C5CCCCC5)cc4N(c4cc(C(C)(C)C)cc(C(C)(C)C)c4)c4cccc2c43)cc(C(C)(C)C)c1]

Example 1 was synthesized according to

AAV5 (94% yield), wherein 3,5-di-tert-butylaniline hydrochloride (CAS 110014-59-0) was used as reactant E0.1;

AAV6 (44% yield), wherein 1,3-dibromo-2-chlorobenzene was used as reactant E1;

AAV3 (47% yield);

and AAV4 (70% yield).

MS (HPLC-MS), ionization source: APPI, m/z (retention time): 809:90 (9:27 min).

### Example 2

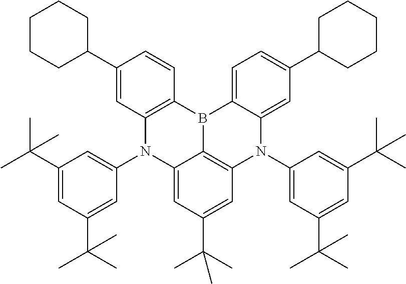 [SMILES: CC(C)(C)c1cc(N2c3cc(C4CCCCC4)ccc3B3c4ccc(C5CCCCC5)cc4N(c4cc(C(C)(C)C)cc(C(C)(C)C)c4)c4cc(C(C)(C)C)cc2c43)cc(C(C)(C)C)c1]

Example 1 was synthesized according to

AAV5 (94% yield), wherein 3,5-di-tert-butylaniline hydrochloride (CAS 110014-59-0) was used as reactant E0.1;

AAV6 (10% yield), wherein 1,3-dibromo-5-tert-butyl-2-chlorobenzene (CAS 1000578-25-5) was used as reactant E1;

and AAV7 (25% yield).

MS (HPLC-MS), ionization source: APCI, m/z (retention time): 865.90 (9.82 min).

Example 1 was tested in OLED D1, which was fabricated with the following structure:

| Layer # | Thickness | D1 |
|---|---|---|
| 9 | 100 nm | Al |
| 8 | 2 nm | Liq |
| 7 | 11 nm | NBPhen |
| 6 | 20 nm | MAT1 |
| 5 | 20 nm | MAT2 (98%):Example 1 (2%) |
| 4 | 10 nm | MAT3 |
| 3 | 50 nm | MAT4 |
| 2 | 7 nm | HAT-CN |
| 1 | 50 nm | ITO |
| Substrate | | glass |

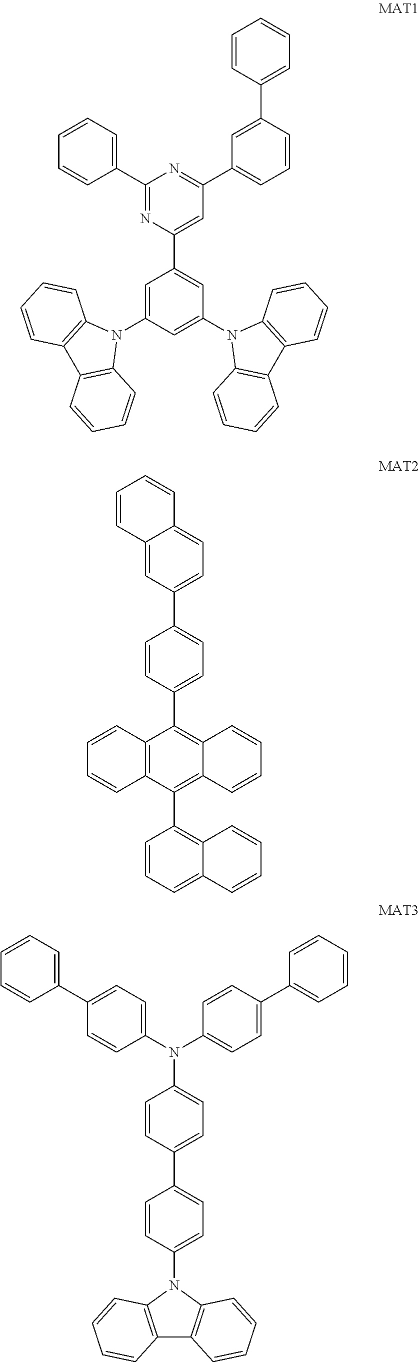

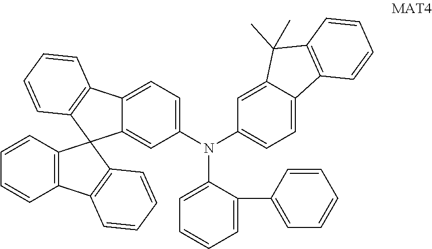 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

OLED D1 yielded an external quantum efficiency (EQE) at 1000 cd/m² of 10.5%. The emission maximum is at 454 nm with a FWHM of 26 nm at 3.8 V. The corresponding CIEx value is 0.14 and the CIEy value is 0.06.

Additional Examples of Organic Molecules of the disclosure

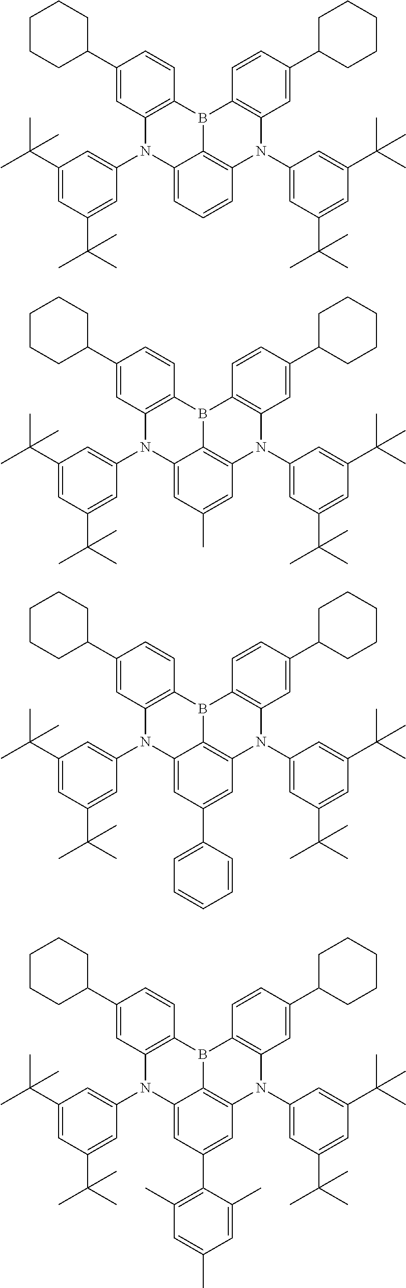

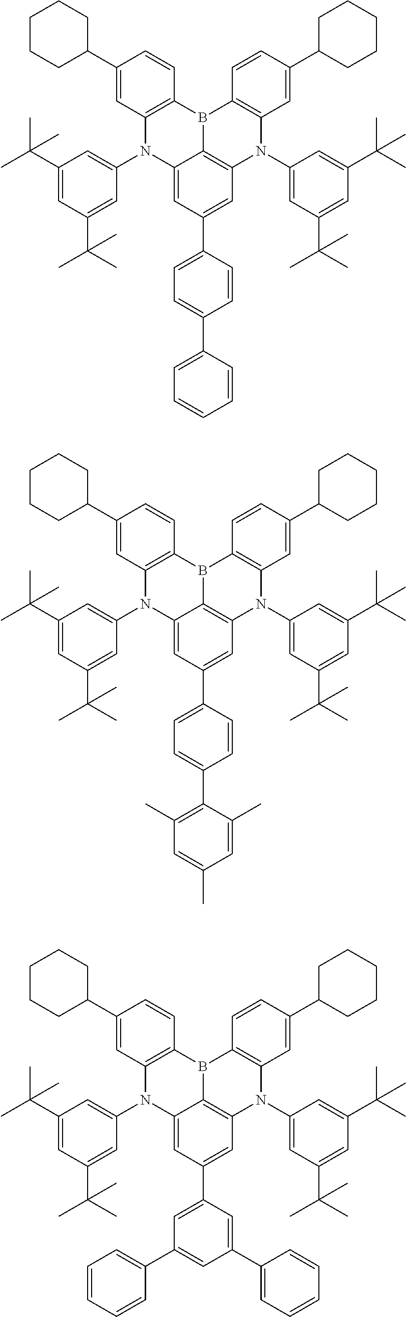

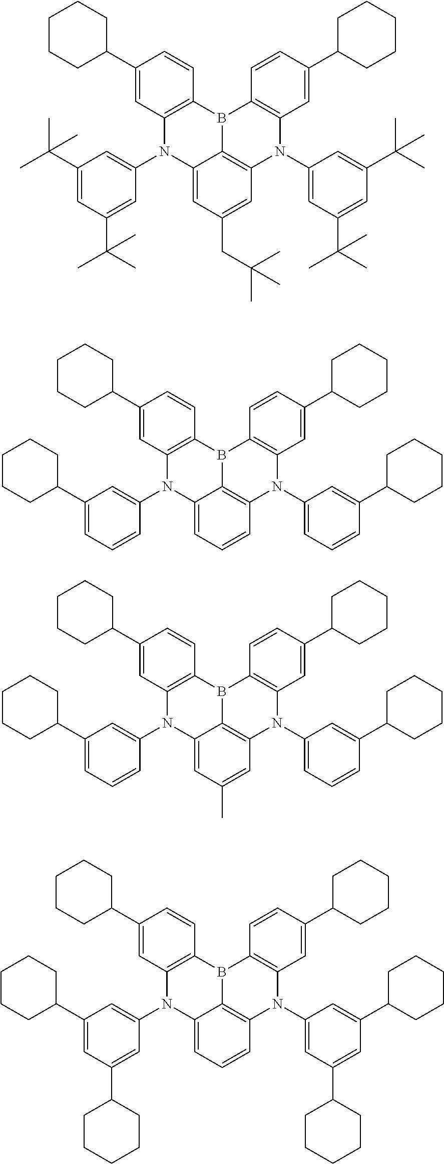

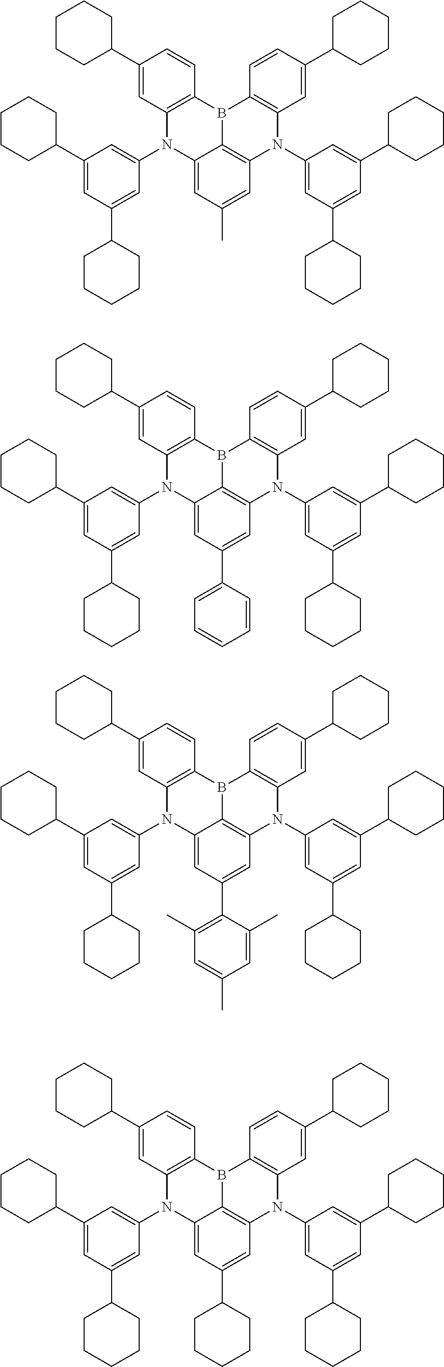

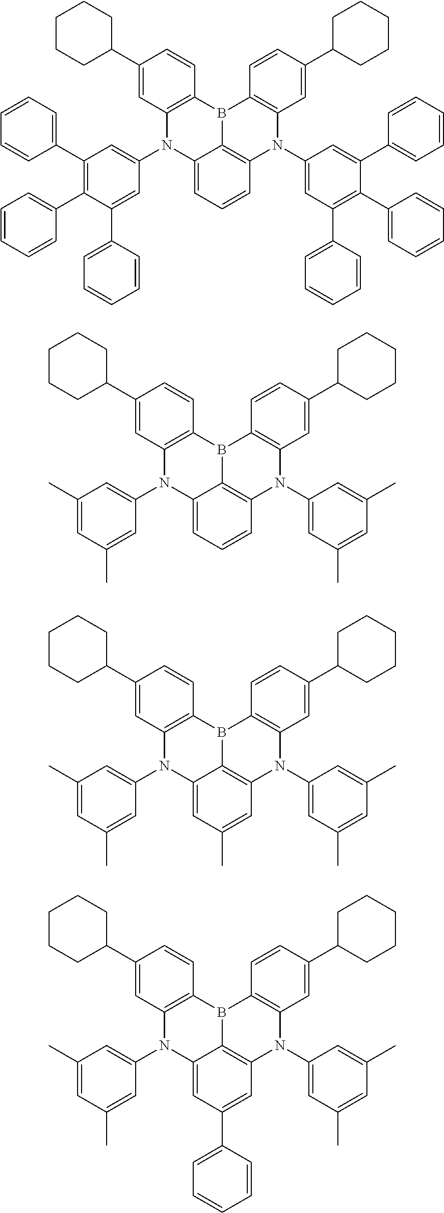

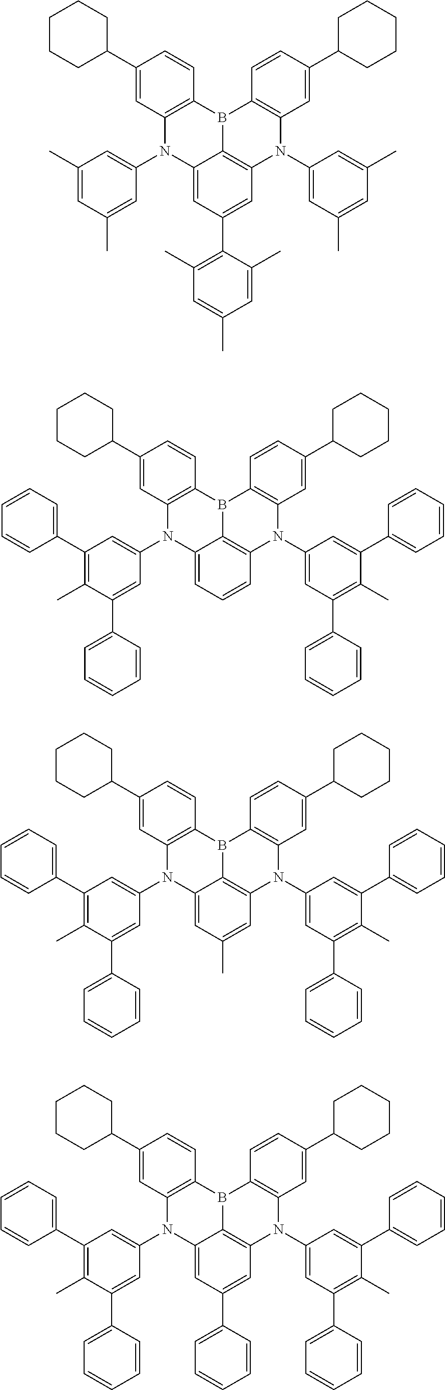 [SMILES: Cc1cc(C)cc(N2c3cc(C4CCCCC4)ccc3B3c4ccc(C5CCCCC5)cc4N(c4cc(C)cc(C)c4)c4cc(-c5c(C)cc(C)cc5C)cc2c43)c1 ; Cc1c(-c2ccccc2)cc(N2c3cc(C4CCCCC4)ccc3B3c4ccc(C5CCCCC5)cc4N(c4cc(-c5ccccc5)c(C)c(-c5ccccc5)c4)c4cccc2c43)cc1-c1ccccc1 ; Cc1cc2c3c(c1)N(c1cc(-c4ccccc4)c(C)c(-c4ccccc4)c1)c1cc(C4CCCCC4)ccc1B3c1ccc(C3CCCCC3)cc1N2c1cc(-c2ccccc2)c(C)c(-c2ccccc2)c1 ; Cc1c(-c2ccccc2)cc(N2c3cc(C4CCCCC4)ccc3B3c4ccc(C5CCCCC5)cc4N(c4cc(-c5ccccc5)c(C)c(-c5ccccc5)c4)c4cc(-c5ccccc5)cc2c43)cc1-c1ccccc1]

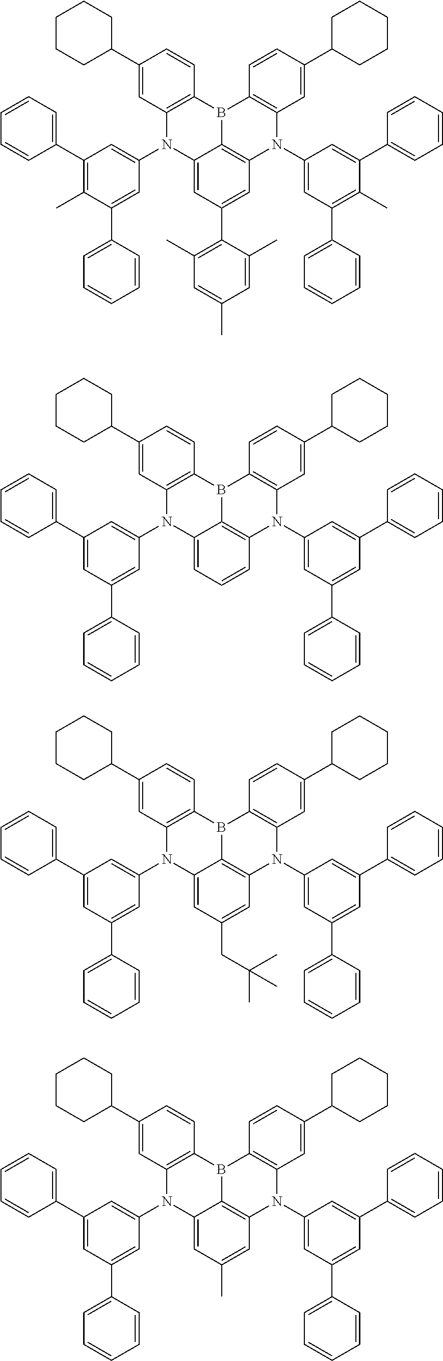

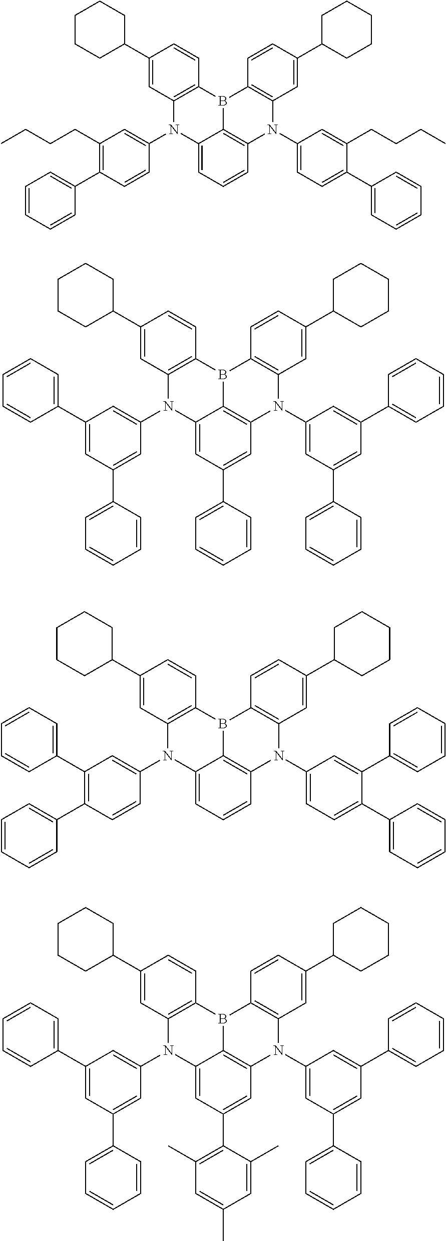 [SMILES: CCCCc1cc(N2c3cc(C4CCCCC4)ccc3B3c4ccc(C5CCCCC5)cc4N(c4ccc(-c5ccccc5)c(CCCC)c4)c4cccc2c43)ccc1-c1ccccc1 ; c1ccc(-c2cc(-c3ccccc3)cc(N3c4cc(C5CCCCC5)ccc4B4c5ccc(C6CCCCC6)cc5N(c5cc(-c6ccccc6)cc(-c6ccccc6)c5)c5cc(-c6ccccc6)cc3c54)c2)cc1 ; c1ccc(-c2ccc(N3c4cc(C5CCCCC5)ccc4B4c5ccc(C6CCCCC6)cc5N(c5ccc(-c6ccccc6)c(-c6ccccc6)c5)c5cccc3c54)cc2-c2ccccc2)cc1 ; Cc1cc(C)c(-c2cc3c4c(c2)N(c2cc(-c5ccccc5)cc(-c5ccccc5)c2)c2cc(C5CCCCC5)ccc2B4c2ccc(C4CCCCC4)cc2N3c2cc(-c3ccccc3)cc(-c3ccccc3)c2)c(C)c1]

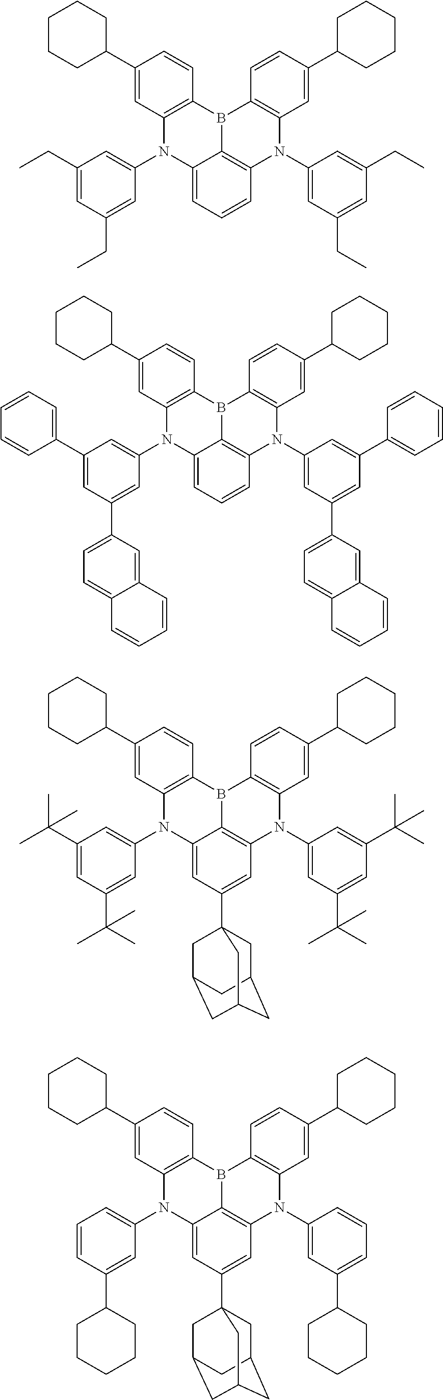

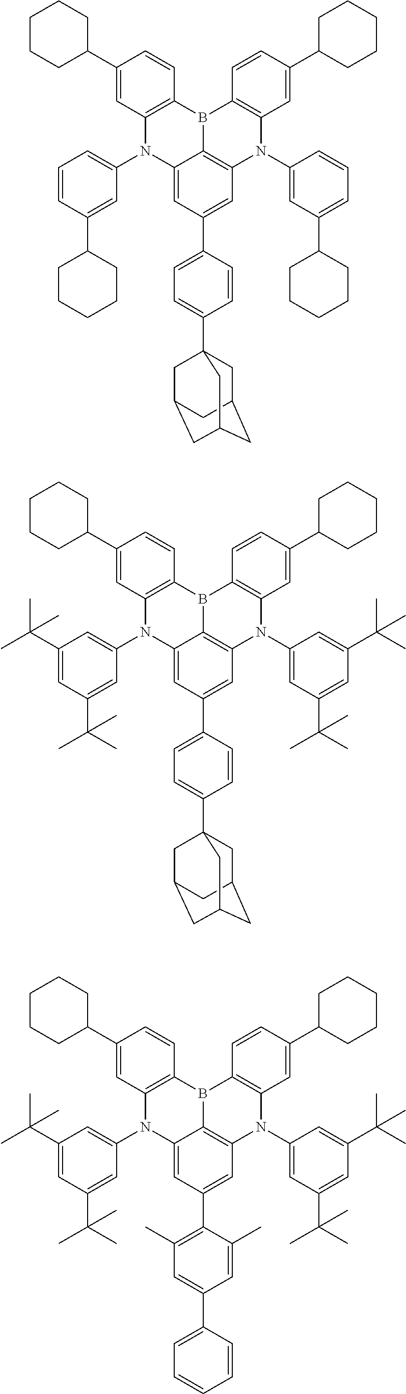

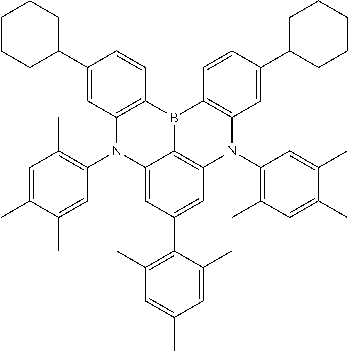 [SMILES: Cc1cc(C)c(-c2cc3c4c(c2)N(c2cc(C)c(C)cc2C)c2cc(C5CCCCC5)ccc2B4c2ccc(C4CCCCC4)cc2N3c2cc(C)c(C)cc2C)c(C)c1]

1. An organic molecule, comprising a structure of Formula I: 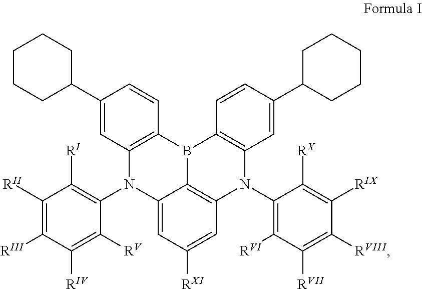
wherein
each of R^{I}, R^{II}, R^{III}, R^{IV}, R^{V}, R^{VI}, R^{VII}, R^{VIII}, R^{IX}, R^{X} and R^{XI} is independently at least one selected from the group consisting of:
hydrogen, deuterium, halogen,
C₁-C₁₂-alkyl,
wherein optionally one or more hydrogen atoms are independently substituted by R⁵;
C₆-C₁₈-aryl,
wherein optionally one or more hydrogen atoms are independently substituted R⁵, and
combinations thereof; R⁵ is at each occurrence independently at least one selected from the group consisting of:
hydrogen, deuterium
C₁-C₁₂-alkyl,
C₆-C₁₈-aryl, and
combinations thereof,
wherein optionally one or more hydrogen atoms are independently substituted by substituents;
at least one of R^{I}, R^{II}, R^{III}, R^{IV}, or R^{V} and at least one of R^{VI}, R^{VII}, R^{VIII}, R^{IX} or R^{X} are each independently at least one selected from the group consisting of:
C₁-C₁₂-alkyl,
wherein optionally one or more hydrogen atoms are independently substituted by R⁵;
C₆-C₁₈-aryl,
wherein optionally one or more hydrogen atoms are independently substituted by R⁵, and
combinations thereof;
wherein optionally, each hydrogen is independently substituted by deuterium or halogen.

2. The organic molecule according to claim 1, wherein each of R^{I}, R^{II}, R^{III}, R^{IV}, R^{V}, R^{VI}, R^{VII}, R^{VIII}, R^{IX}, R^{X} and R^{XI} is independently at least one selected from the group consisting of:
hydrogen, deuterium, halogen, Me, ⁱPr, ^{t}Bu,
cyclohexyl, which is optionally substituted with one or more substituents independently selected from the group consisting of Me, ⁱPr, ^{t}Bu and Ph,
Ph, which is optionally substituted with one or more substituents independently selected from the group consisting of Me, ⁱPr, ^{t}Bu, cyclohexyl and Ph, and combinations thereof.

3. The organic molecule according to claim 1, wherein at least two selected from among R^{I}, R^{II}, R^{III}, R^{IV}, and R^{V} and at least two selected from among R^{VI}, R^{VII}, R^{VIII}, R^{IX} and R^{X} are each independently at least one selected from the group consisting of Me, ⁱPr, ^{t}Bu, cyclohexyl, Ph, and combinations thereof.

4. The organic molecule according to claim 1, wherein R^{X} is at least one selected from the group consisting of hydrogen, deuterium, Me, ⁱPr, ^{t}Bu, cyclohexyl, Ph, and combinations thereof.

5. The organic molecule according to claim 1, comprising a structure of Formula Ia:

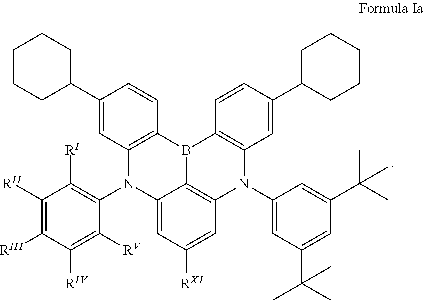

6. The organic molecule according to claim 1, comprising a structure of Formula Ib:

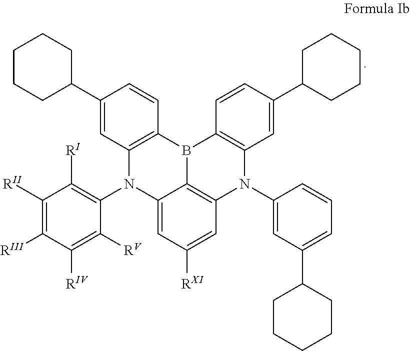

7. The organic molecule according claim 1, comprising a structure of Formula Ic:

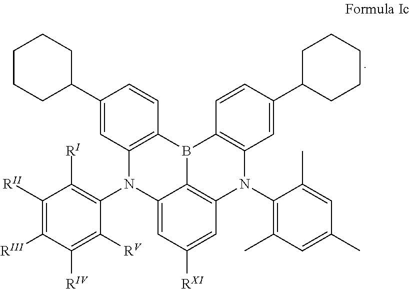

8. The organic molecule according to claim 1, comprising a structure of Formula Id:

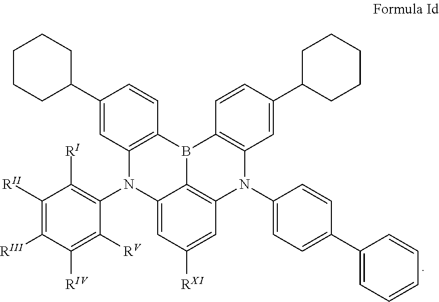

9. The organic molecule according claim 1, comprising a structure of Formula Ie:

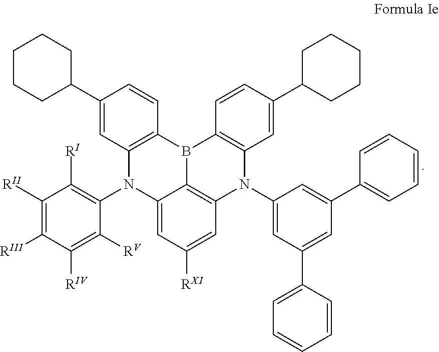

10. An optoelectronic device comprising:
the organic molecule according to claim 1 configured to be a luminescent emitter in the optoelectronic device.

11. The optoelectronic device according to claim 10, wherein the optoelectronic device is at least one selected from the group consisting of:
organic light-emitting diodes (OLEDs),
light-emitting electrochemical cells,
OLED-sensors,
organic diodes,
organic solar cells,
organic transistors,
organic field-effect transistors,
organic lasers,
down-conversion elements, and
combinations thereof.

12. A composition, comprising:
(a) the organic molecule according to claim 1, in as an emitter and/or a host, and
(b) an emitter and/or a host material, which differs from the organic molecule, and
(c) optionally, a dye and/or a solvent.

13. An optoelectronic device, comprising the organic molecule according to claim 1 or a composition comprising the organic molecule, the optoelectronic device being selected from the group consisting of organic light-emitting diodes (OLEDs), light-emitting electrochemical cells, OLED-sensor, organic diodes, organic solar cells, organic transistors, organic field-effect transistors, organic lasers, down-conversion elements, and combinations thereof.

14. The optoelectronic device according to claim 13, comprising:
a substrate,
an anode, and
a cathode, wherein the anode or the cathode is on the substrate, and
a light-emitting layer between the anode and the cathode, the light-emitting layer comprising the organic molecule or the composition.

15. A method for producing an optoelectronic device, the method comprising:
processing the organic molecule according to claim 1 or a composition comprising the organic molecule, to produce the optoelectronic device.

16. The method according to claim 15, wherein the processing of the organic molecule is performed by vacuum evaporation or from a solution.
